(19) United States
(12) Patent Application Publication
(10) Pub. No.: US 2015/0294726 A1
(43) Pub. Date: Oct. 15, 2015

(54) NAND-TYPE FLASH MEMORY DEVICE AND METHOD OF PROGRAMMING THE SAME

(71) Applicants: JAE-SUNG SIM, HWASEONG-SI (KR); JOO-HEON KANG, SEOUL (KR); KYUNG-JUN SHIN, SEOUL (KR)

(72) Inventors: JAE-SUNG SIM, HWASEONG-SI (KR); JOO-HEON KANG, SEOUL (KR); KYUNG-JUN SHIN, SEOUL (KR)

(21) Appl. No.: 14/672,372

(22) Filed: Mar. 30, 2015

(30) Foreign Application Priority Data
Apr. 9, 2014 (KR) 10-2014-0042563

(51) Int. Cl. G11C 16/10; G11C 16/04

(52) U.S. Cl. CPC G11C 16/10; G11C 16/0483

(57) ABSTRACT

A NAND-type flash memory device and method for programming the NAND-type flash memory device are provided. The method may include applying a voltage of 0 V to an unselected string select line, applying the voltage of 0 V to a selected bit line, applying a supply voltage to a selected string select line, and applying a dummy pass voltage to a dummy word line, the dummy pass voltage being in a range between 0 V to a pass voltage. The method may further include applying the supply voltage to an unselected bit line, applying the pass voltage to a selected word line, applying the pass voltage to an unselected word line; and applying a program voltage to the selected word line.

### CROSS-REFERENCE TO RELATED APPLICATION

A claim for priority under 35 U.S.C. §119 is made to Korean Patent Application No. 10-2014-0042563 filed on Apr. 9, 2014,in the Korean Intellectual Property Office, the entire contents of which are hereby incorporated by reference.

### BACKGROUND

Embodiments of the inventive concept relate to a method of programming a nonvolatile memory device, and more particularly, to a method of programming a NAND-type flash memory device capable of improving a program performance.

Semiconductor memory devices may be classified as volatile memory devices and nonvolatile memory devices. A volatile memory device may store data as a logic state of a bistable flip-flop or charge or discharge of a capacitor. The volatile memory device only stores or reads data only while power is on, and loses data when powered off.

A nonvolatile memory device, such as an electrically erasable programmable read-only-memory (EEPROM) and a flash memory device, continues to store data even when power is off. The nonvolatile memory device may be used to store programs and data in a wide range of applications, such as computers and communication devices. Since an EEPROM is electrically erasable and programmable, the EEPROM has been widely used as a system programming device or an auxiliary memory device that needs to be continuously updated.

A NAND-type flash memory device is another type of nonvolatile memory device. A NAND-type flash memory device is generally more highly integrated than a NOR-type flash memory device, for example. The NAND-type flash memory device includes a memory cell array to store data, and the memory cell array includes a plurality of cell strings (also called NAND strings). Each memory cell of the NAND-type flash memory device may perform erase and program operations using a Fowler-Nordheim (F-N) tunneling current.

### SUMMARY

Embodiments of the inventive concept provide methods of programming a NAND-type flash memory device capable of improving precharge efficiency of unselected cell strings in a program mode. Other embodiments of the inventive concept provide a NAND-type flash memory device capable of improving precharge efficiency of unselected cell strings in a program mode.

The technical objectives of the inventive concept are not limited herein; other objectives may become apparent to those of ordinary skill in the art based on the following descriptions.

In accordance with an aspect of the inventive concept, a method is provided for programming a NAND-type flash memory device. The method includes applying a supply voltage to a selected string select line; applying a dummy pass voltage to a dummy word line, the dumpy pass voltage being in a range between 0 V to a pass voltage; applying the supply voltage to an unselected bit line; applying a voltage of 0 V to a selected bit line; applying the pass voltage to a selected word line; applying the pass voltage to an unselected word line; and applying a program voltage to the selected word line.

The method may further include initially applying the voltage of 0V to the unselected bit line. Also, the method may further include applying the voltage of 0 V to a ground select line; and applying a first voltage to a common source line, the first voltage being greater than 0 V and less than or equal to the supply voltage. The method may further include applying the supply voltage a ground select line, and then applying the voltage of 0 V to the ground select line. The method may further include applying a voltage of 0 V to an unselected string select line.

In a program mode, time points of applying voltages to the selected string select line, the dummy word line and the unselected bit line may be different.

In a program mode, the supply voltage may be applied to the selected string select line, then after a first time interval, the dummy pass voltage may be applied to the dummy word line, and then after a second time interval, the supply voltage may be applied to the unselected bit line. Each of the first time and the second time intervals may be at least 1 μs.

In a program mode, a first voltage having a voltage greater than or equal to the supply voltage added to a threshold voltage of a string select transistor may be applied to the selected string select line during a bit line setup period, and then after a first time interval, a voltage applied to the selected string select line may be lowered to the supply voltage. Also, the first voltage may be applied to the selected string select line, and then after a second time interval, the dummy pass voltage may be applied to the dummy word line. The second time interval may be at least 1 μs. Also, in the program mode, the supply voltage may be applied to the unselected bit line when the first voltage is applied to the selected string select line.

In accordance with another aspect of the inventive concept, a method is provided for programming a NAND-type flash memory device. The method includes applying a supply voltage to an unselected string select line; applying the supply voltage to a selected string select line; applying a dummy pass voltage to a dummy word line, the dumpy pass voltage being in a range between 0 V to a pass voltage; applying the supply voltage to a selected bit line; applying the supply voltage to an unselected bit line; and applying a voltage of 0 V to the selected bit line.

In a program mode, the supply voltage may be applied to the unselected string select line during an initial precharge period.

In a program mode, the supply voltage may be applied to the selected string select line, then after a first time interval, the dummy pass voltage may be applied to the dummy word line, and then after a second time interval, the supply voltage may be applied to the unselected bit line.

In a program mode, a first voltage having a voltage greater than or equal to the supply voltage added to a threshold voltage of a string select transistor may be applied to the selected string select line during a bit line setup period, and then after a first time interval, the supply voltage may be applied to the selected string select line. Also, the first voltage may be applied to the selected string select line, and then after a second time interval, the dummy pass voltage may be applied to the dummy word line.

In accordance with an aspect of the inventive concept, a memory device, which may be NAND-type flash memory device, includes a memory cell array and a row control circuit. The memory cell array includes a dummy word line, a plurality of bit lines, a plurality of word lines, a string select line and a ground select line. The row control circuit is configured to generate a program voltage, a pass voltage, and a dummy pass voltage having a voltage in a range between 0 V to the pass voltage, and to control electric potentials of the dummy word line, the word lines, the string select line and the ground select line. In a program mode, the row control circuit applies a supply voltage to the string select line, the dummy pass voltage to the dummy word line, the supply voltage to an unselected bit line of the bit lines, a voltage of 0 V to a selected bit line of the bit lines, the pass voltage to a selected word line of the word lines, the pass voltage to an unselected word line of the word lines, and a program voltage to the selected word line.

The memory device may further include a page buffer circuit having page buffers corresponding to the bit lines, respectively; a common source line control circuit configured to control electric potential of a common source line to be 0 V and then a voltage approximately equal to the supply voltage in the program mode; and a column gate circuit configured to electrically connect or disconnect the page buffer circuit with an input/output circuit in response to column select signals.

### BRIEF DESCRIPTION OF THE DRAWINGS

Exemplary embodiments of the inventive concept will be more clearly understood from the following description taken in conjunction with the accompanying drawings, in which:

FIG. 1 is a circuit diagram illustrating a part of a memory cell array included in a conventional vertical NAND-type (VNAND) flash memory device;

FIG. 2 is a timing diagram illustrating an example of a program operation of the conventional VNAND flash memory device;

FIG. 3 is a timing diagram illustrating another example of a program operation of a conventional VNAND flash memory device;

FIGS. 4 and 5 are diagrams illustrating a threshold voltage of a memory transistor connected to a dummy word line increasing more compared to a memory transistor connected to a normal word line in a VNAND flash memory device including the dummy word line;

FIG. 6 is a circuit diagram illustrating a NAND-type flash memory device, according to an embodiment of the inventive concept;

FIG. 7 is a circuit diagram illustrating a part of a memory cell array included in the NAND-type flash memory device of FIG. 6, according to an embodiment of the inventive concept;

FIG. 8 is a timing diagram illustrating an example of a program operation of a NAND-type flash memory device, according to an embodiment of the inventive concept;

FIG. 9 is a diagram illustrating a hot carrier injection and charge trapping generated in a channel area between a dummy word line (DMY_S) adjacent to a string select line and the string select line, according to an embodiment of the inventive concept;

FIG. 10 is a timing diagram illustrating an example of a program operation of a NAND-type flash memory device, according to another embodiment of the inventive concept;

FIG. 11 is a timing diagram illustrating an example of a program operation of a NAND-type flash memory device, according to still another embodiment of the inventive concept;

FIG. 12 is a timing diagram illustrating an example of a program operation of a NAND-type flash memory device, according to yet another embodiment of the inventive concept;

FIG. 13 is a timing diagram illustrating an example of a program operation of a NAND-type flash memory device, according to yet another embodiment of the inventive concept;

FIG. 14 is a timing diagram illustrating an example of a program operation of a NAND-type flash memory device, according to yet another embodiment of the inventive concept;

FIG. 15 is a circuit diagram illustrating two types of program modes that may apply to a NAND-type flash memory device, according to an embodiment of the inventive concept;

FIGS. 16 to 21 are flowcharts illustrating methods of programming a NAND-type flash memory device, according to embodiments of the inventive concept;

FIG. 22 is a perspective view of a structure of a NAND-type flash memory device, according to an embodiment of the inventive concept;

FIG. 23 is a perspective view of a cell region of the NAND-type flash memory device illustrated in FIG. 22, according to an embodiment of the inventive concept;

FIGS. 24 and 25 are perspective views illustrating examples of a cell transistor included in the cell region of FIG. 23, according to embodiments of the inventive concept;

FIG. 26 is a circuit diagram of an example of a memory cell array of the NAND-type flash memory device illustrated in FIG. 22, according to an embodiment of the inventive concept:

FIG. 27 is a block diagram of a memory system including the NAND-type flash memory device, according to embodiments of the inventive concept; and

FIG. 28 is a block diagram of an information processing system including the NAND-type flash memory device, according to embodiments of the inventive concept.

### DETAILED DESCRIPTION OF THE EMBODIMENTS

Embodiments will be described in detail with reference to the following description and accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to one of ordinary skill in the art. That is, various embodiments cover all modifications, equivalents, and alternatives falling within the spirit and scope of the inventive concept. Accordingly, known processes, elements, and techniques are not described with respect to some of the embodiments. Unless otherwise noted, like reference numerals denote like elements throughout the attached drawings and written description, and thus descriptions may not be repeated. The drawings are not necessarily to scale, emphasis instead being placed upon illustrating the principles of the inventive concepts. Also, in the drawings, the sizes and relative sizes of layers and regions may be exaggerated for clarity.

It will be understood that, although the terms “first,” “ second,” “ third,” etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the scope of the present inventive concept.

It will be understood that when an element or layer is referred to as being “on,” “connected to,” or “coupled with” another element or layer, it can be directly on, connected, or coupled to the other element or layer, or intervening elements or layers may be present. In contrast, when an element is referred to as being “directly on,” “directly connected to,” or “directly coupled with” another element or layer, there are no intervening elements or layers present. Like numerals refer to like elements throughout. As used herein, the term “and/or” includes any and all combinations of one or more of the associated listed items. The term “exemplary” is intended to refer to an example or illustration.

The terminology used herein is for the purpose of describing particular embodiments only and is not intended to be limiting of the present inventive concept. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Meanwhile, when it is possible to implement an embodiment in any other way, a function or an operation specified in a specific block may be performed differently from a flow specified in a flowchart. For example, two consecutive blocks may perform the respective functions or operations simultaneously, and the two blocks may perform the respective functions or operations in a different order according to a related operation or function.

Embodiments of the inventive concept will now be described more fully with reference to the accompanying drawings, in which embodiments of the inventive concept are shown.

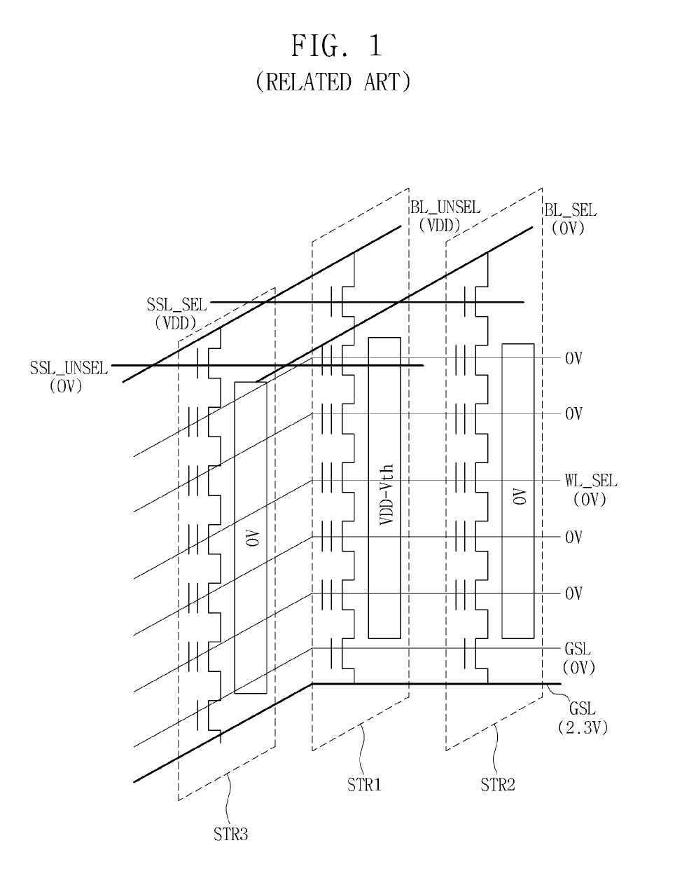

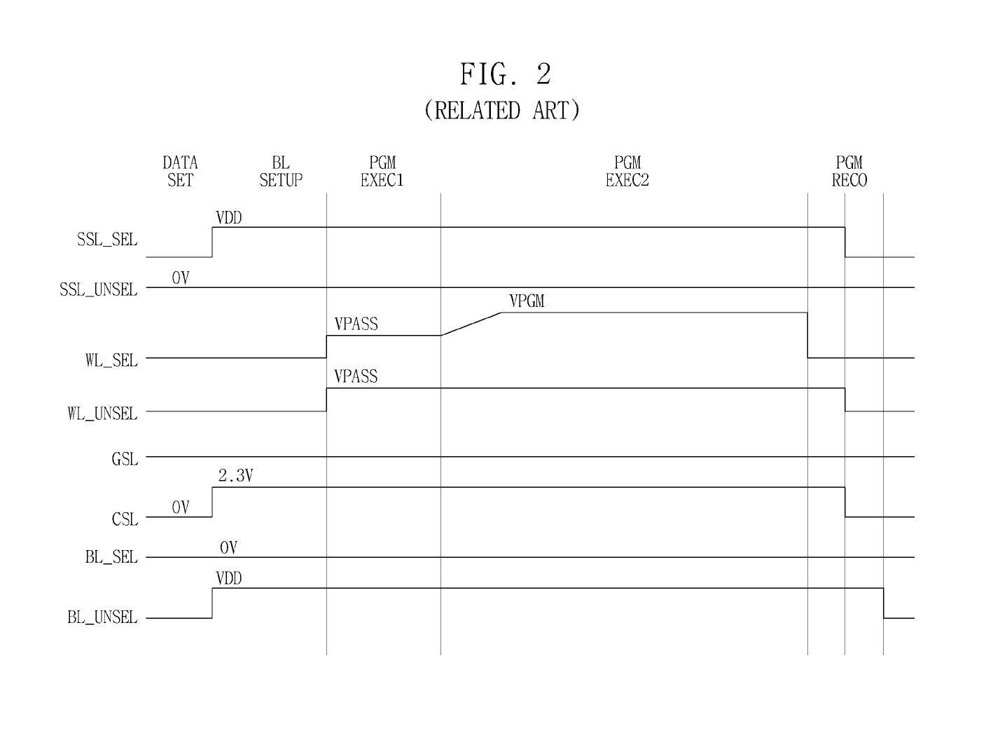

FIG. 1 is a circuit diagram illustrating part of a memory cell array included in a conventional vertical NAND-type (VNAND) flash memory device, and FIG. 2 is a timing diagram illustrating an example of a program operation of the conventional VNAND flash memory device. In FIG. 2, waveforms of voltages may be applied to a selected string select line SSL_SEL, an unselected string select line SSL_UNSEL, a selected word line WL_SEL, an unselected word line WL_UNSEL, a ground select line GSL, a common source line CSL, a selected bit line BL_SEL, and an unselected bit line BL_UNSEL according to a process of programming The process of programming may include a data setting DATA_SET, a bit line setup BL SETUP, a first program execution PGM EXEC1, a second program execution PGM EXEC2 and a program recover PGM RECO. A pass voltage V_{PASS} may be applied to the unselected word line WL_UNSEL during the first program execution PGM EXEC1 and the second program execution PGM EXEC2. The pass voltage V_{PASS} may be applied to the selected word line WL_SEL during the first program execution PGM EXEC1, and a program voltage VPGM may be applied to the selected word line WL_SEL during the second program execution PGM EXEC2.

The VNAND flash memory device has a gate-all-around (GAA) structure having a fully depleted channel, and therefore may have an excellent program inhibition property during a program inhibition period. In the conventional VNAND flash memory device, a supply voltage V_{DD} is applied to a string select line (SSL) and a bit line (BL), and therefore a channel of a program inhibited string is precharged by a voltage of (V_{DD}−VTH_SSL). Then, the precharged voltage may additionally increase a boosting level of the channel when the voltage of a word line (WL) changes from 0 V to the pass voltage V_{PASS}. The VNAND flash memory device may have the unselected SSL SSL_UNSEL to which the voltage of 0 V is applied in a selected block, and therefore 0 V and the V_{DD} or 0 V and 0 V may be applied to the unselected SSL SSL_UNSEL and the BL, respectively. In this condition, in a program inhibit operating mode, a channel precharge for increasing a boosting level of the string connected to the unselected SSL SSL_UNSEL may not be accomplished. Referring to FIG. 1, a string STR1 is connected to the unselected BL BL_UNSEL and the selected SSL SSL_SEL. A string STR2 is connected to the selected BL BL_SEL and the selected SSL SSL_SEL. A string STR3 is connected to the unselected BL BL_UNSEL and the unselected SSL SSL_UNSEL. The supply voltage V_{DD} may be applied to the unselected BL BL_UNSEL, and the ground voltage (0 V) may be applied to the selected BL BL_SEL. The ground voltage (0 V) may be applied to the unselected SSL SSL_UNSEL, and the supply voltage V_{DD} may be applied to the selected SSL SSL_SEL. The voltage of 0 V may be maintained in the channels of memory transistors included in the string STR2, and the voltage of (V_{DD}−Vₜₕ) may be maintained in the channels of memory transistors included in the string STR1. The voltage of (V_{DD}−Vₜₕ) rather than the 0 V may be maintained in the channels of memory transistors included in the string STR3. Therefore, the channels of memory transistors included in the string connected to the unselected BL BL_UNSEL and the unselected SSL SSL_UNSEL may not be precharged.

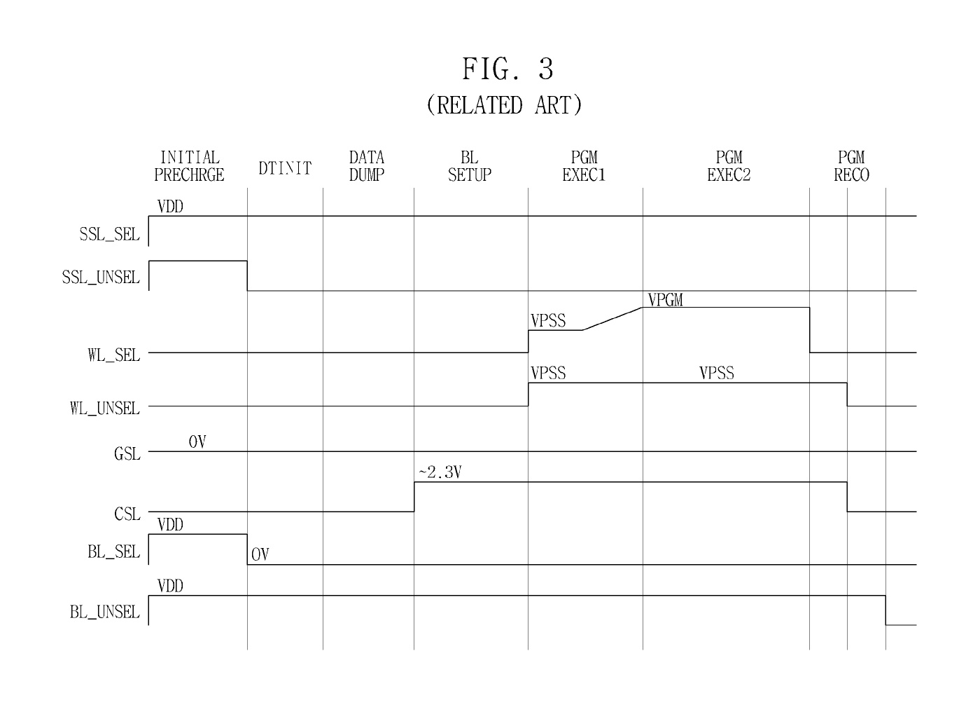

FIG. 3 is a timing diagram illustrating another example of a program operation of a conventional VNAND flash memory device. The method of programming shown in FIG. 3 may precharge the channels of memory transistors included in the string connected to the unselected SSL SSL_UNSEL using an operational mode of unselected string initial precharge (USIP). The process of programming may include an initial precharge, a data initializing DTINIT, a data dump DATA DUMP, a BL setup BL SETUP, a first program execution PGM EXEC1, a second program execution PGM EXEC2, and a program recover PGM RECO. Referring to FIG. 3, unlike the method of programming shown in FIG. 2, during the initial precharge, a high voltage, e.g. V_{DD}, may be applied to the unselected SSL SSL_UNSEL. Further, the supply voltage V_{DD} may be applied to the selected BL BL_SEL during the initial precharge, and the voltage of 0 V may be applied when the initial precharge is completed.

The path from the BL to channels of memory transistors connected to the selected WL which is to be programmed may be conductive to precharge the channels of the memory transistors included in the string of a memory cell array using the method of programming shown in FIGS. 2 and 3. During the BL setup BL SETUP, a threshold voltage VTH_WL of a memory transistor connected to the WL should have at least a value of—(V_{DD}−VTH_SSL) because 0 V is applied to the WLs WL_SEL and WL_UNSEL. The memory transistor connected to a normal WL which is erased may satisfy this condition, but the memory transistor connected to a dummy WL may not have a sufficiently low threshold voltage VTH_WL, and therefore may not satisfy this condition.

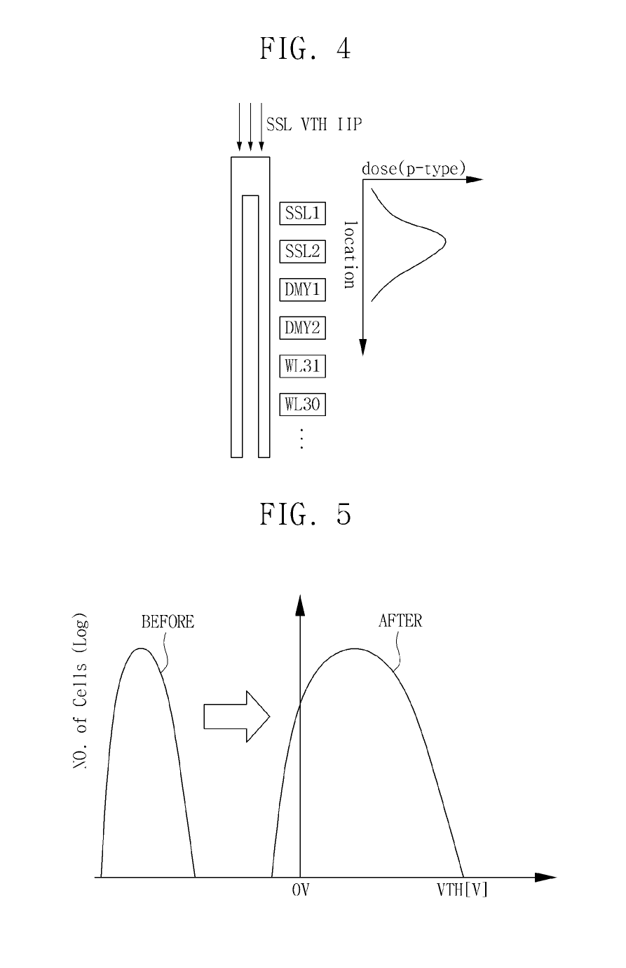

FIGS. 4 and 5 are diagrams illustrating the reason why a threshold voltage of a memory transistors connected to a dummy WL is increased more compared to a memory transistors connected to a normal WL in a VNAND flash memory device including the dummy WL.

Referring to FIGS. 4 and 5, the threshold voltage of memory transistors connected to a dummy WL may increase because of two reasons. First, as shown in FIG. 4, the threshold voltage of memory transistors connected to the dummy WL adjacent to a SSL may increase by the influence of ion implantation SSL VTH IIP for adjusting the threshold voltage (Vₜₕ) of the SSL. In FIG. 4, a first dummy WL DMY1 may correspond to the dummy WL DMY_S adjacent to the SSL. Second, as shown in FIG. 5, the threshold voltage of memory transistors connected to the dummy WL DMY_S may increase by repeating program/erase operations. Therefore, the memory transistors connected to the dummy WL DMY_S may not be turned on, causing a precharge voltage not to be transferred to channels of memory transistors connected to a WL.

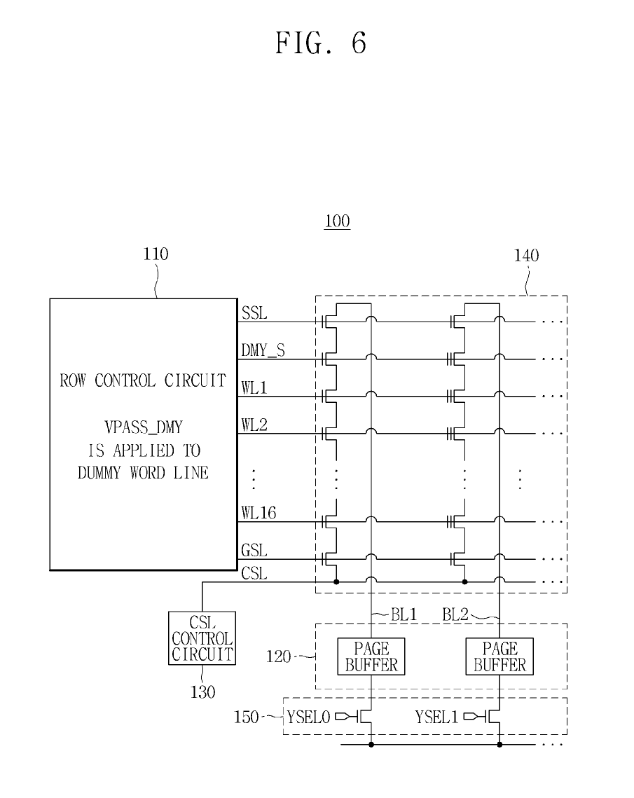

FIG. 6 is a circuit diagram illustrating a NAND-type flash memory device 100, according to an embodiment of the inventive concept.

Referring to FIG. 6, the NAND-type flash memory device 100 includes a row control circuit 110, a page buffer circuit 120, a common source line (CSL) control circuit 130, a memory cell array 140, and a column gate circuit 150.

The row control circuit 110 may generate a program voltage _{VPGM,} a pass voltage V_{PASS}, and a dummy pass voltage VPASS_DMY having a voltage in a range between 0 V to the pass voltage V_{PASS} and applied to a dummy WL DMY_S. The row control circuit 110 may control electric potentials of the dummy WL DMY_S, WLs WL1 to WL16, a SSL SSL, and a ground select line GSL.

In the memory cell array 140, BLs BL1 and BL2 may be arranged in a direction perpendicular to the WLs WL1 to WL16.

The page buffer circuit 120 may include page buffers corresponding to the respective BLs BL1 and BL2, and each of the page buffers may include a sense amplifier. In a read mode, each of the page buffers functions to sense data from a selected memory cell and to transmit the sensed data through the column gate circuit 150 to an input/output (I/O) circuit (not shown). In a program mode, each of the page buffers temporarily stores the data applied through the I/O circuit and the column gate circuit 150. That is, each of the page buffers may function as both a data sensor and a latch. The column gate circuit 150 electrically connects or disconnects the page buffer circuit 120 with the I/O circuit in response to column select signals YSEL0 and YSEL1. The CSL CSL control circuit 130 may control the electric potential of a CSL CSL in the program mode.

The NAND-type flash memory device 100 shown in FIG. 6 performs precharging for memory transistors included in a portion of the memory cell array 140 that is not to be programmed when programming is performed. The NAND-type flash memory device 100 applies the dummy pass voltage VPASS_DMY having a voltage in a range between 0 V to the pass voltage V_{PASS} to the dummy WL DMY_S during the program process, and therefore a voltage precharged in the BL (BL) may be transferred to channels of memory transistors connected to the dummy WL DMY_S. As described hereinafter, in the NAND-type flash memory device 100 according to an embodiment, time points of applying voltages to a selected SSL SSL_SEL, the dummy WL DMY_S, and an unselected BL BL_UNSEL are set differently, and therefore hot carriers are not generated near channels of memory transistors connected to the dummy WL DMY_S. The NAND-type flash memory device 100 may first apply a supply voltage V_{DD} to the selected SSL SSL_SEL, next, the dummy pass voltage VPASS_DMY to the dummy WL DMY_S, and last, the supply voltage V_{DD} to the unselected BL BL_UNSEL. Therefore, the NAND-type flash memory device 100 may turn on memory transistors connected to the dummy WL DMY_S after string select transistors connected to the selected SSL SSL_SEL are fully turned on. Further, the NAND-type flash memory device 100 may apply a voltage having a voltage greater than or equal to (e.g., V_{DD} +VTH_SSL) to the selected SSL SSL_SEL during the BL setup, and therefore string select transistors connected to the selected SSL SSL_SEL maintain an on state and the voltage of the unselected BL BL_UNSEL may be transferred to channels of the string select transistors. Here, VTH_SSL denotes a threshold voltage of a string select transistor connected to a SSL. Therefore, the NAND-type flash memory device 100 eliminate the source of generation of hot carriers, and then applies the supply voltage V_{DD} to the unselected BL BL_UNSEL to stably perform a precharge operation.

Further, in the NAND-type flash memory device 100, the supply voltage V_{DD} is applied to an unselected SSL SSL_UNSEL during an initial precharge period before the BL setup period, and string select transistors connected to the unselected SSL SSL_UNSEL are turned on. Therefore, cell strings connected to the unselected SSL SSL_UNSEL are stably precharged. Also, the program inhibit property of the NAND-type flash memory device 100 and the program performance of the NAND-type flash memory device 100 are improved.

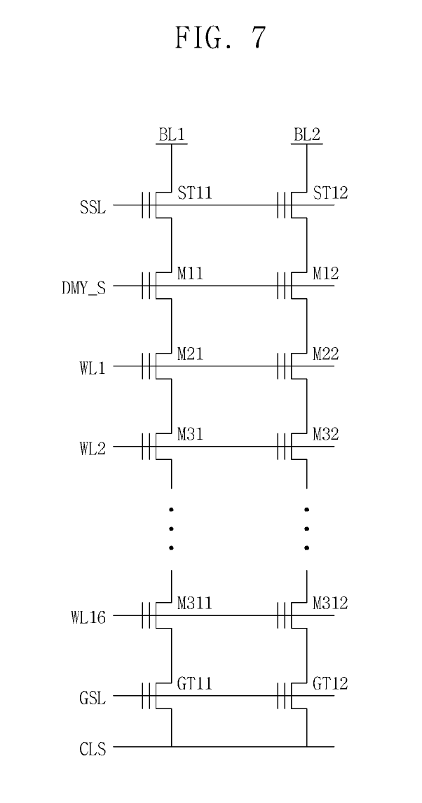

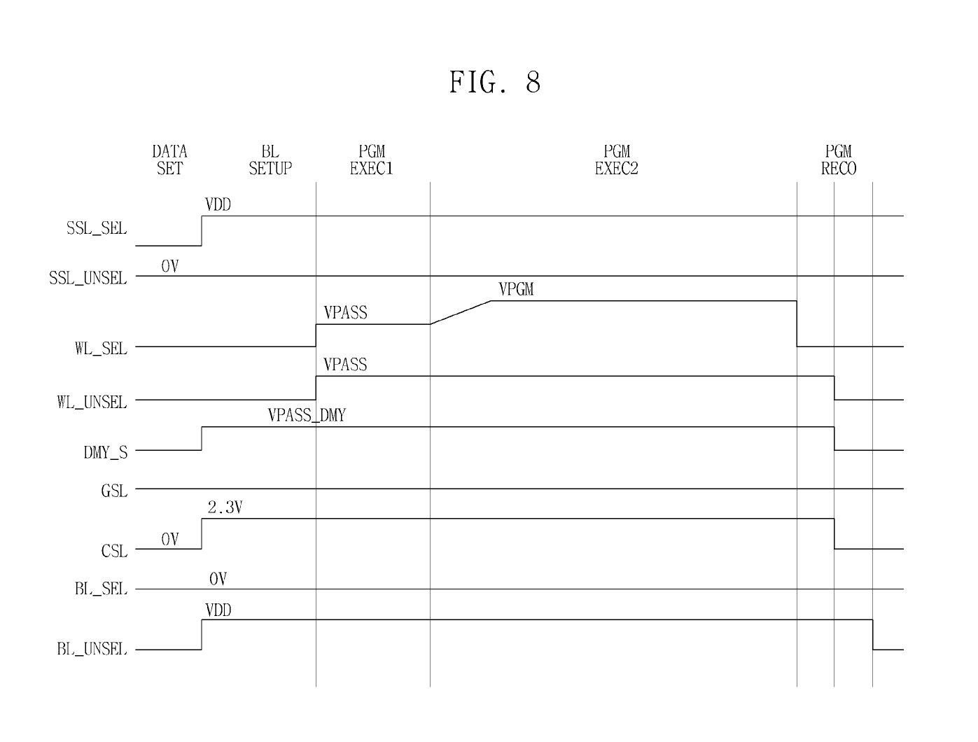

FIG. 7 is a circuit diagram illustrating a part of a memory cell array included in the NAND-type flash memory device of FIG. 6, and FIG. 8 is a timing diagram illustrating an example of a program operation of a NAND-type flash memory device according to an embodiment of the inventive concept.

Referring to FIG. 7, the memory cell array of the NAND-type flash memory device includes a first string connected to a first BL BL1 and a second string connected to a second BL BL2. The first string includes a string select transistor ST11, memory transistors M11 to M311, and a ground select transistor GT11, and the second string includes a string select transistor ST12, memory transistors M12 to M312, and a ground select transistor GT12. The string select transistors ST11 and ST12 are connected to the SSL SSL, and the memory transistors M11 and M12 are connected to the dummy WL DMY_S. The memory transistors M21 and M22 may be connected to the WL WL1, and the memory transistors M311 and M312 are connected to the WL WL16. The ground select transistors GT11 and GT12 are connected to the ground select line GSL. The sources of the ground select transistors GT11 and GT12 are connected to the CSL CSL.

In FIG. 8, waveforms of voltages that may be applied to a selected SSL SSL_SEL, an unselected SSL SSL_UNSEL, a selected WL WL_SEL, an unselected WL WL_UNSEL, a dummy WL DMY_S, a ground select line GSL, a CSL CSL, a selected BL BL_SEL, and an unselected BL BL_UNSEL according to a process of programming The process of programming may include a data setting DATA_SET, a BL setup BL SETUP, a first program execution PGM EXEC1, a second program execution PGM EXEC2, and a program recover PGM RECO. During the programming process, a supply voltage V_{DD} may be applied to the selected SSL SSL_SEL, and a voltage of 0 V may be applied to unselected SSL SSL_UNSEL. For example, the supply voltage V_{DD} may have a voltage of 2.4 V. During the program process, the voltage of 0 V may be applied to the selected BL BL_SEL, and the supply voltage V_{DD} may be applied to the unselected BL BL_UNSEL. During the program process, the voltage of 0 V may be applied to the ground select line GSL, and about 2.3 V (approximately the supply voltage) may be applied to the CSL CSL. A pass voltage V_{PASS} may be applied to the unselected WL WL_UNSEL during the first program execution PGM EXEC1 and the second program execution PGM EXEC2. The pass voltage V_{PASS} may be applied to the selected WL WL_SEL during the first program execution PGM EXEC1, and a program voltage V_{PGM} may be applied to the selected WL WL_SEL during the second program execution PGM EXEC2. For example, the pass voltage V_{PASS} may have a voltage of 9 V and the program voltage V_{PGM} may have a voltage of 20 V. The dummy pass voltage VPASS_DMY having a voltage in a range between 0 V to the pass voltage V_{PASS} may be applied to the dummy WL DMY_S during the program process. Therefore, a voltage precharged in the BL (BL) may be transferred to channels of memory transistors connected to the dummy WL DMY_S.

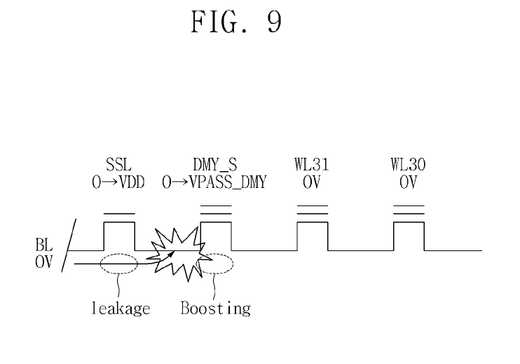

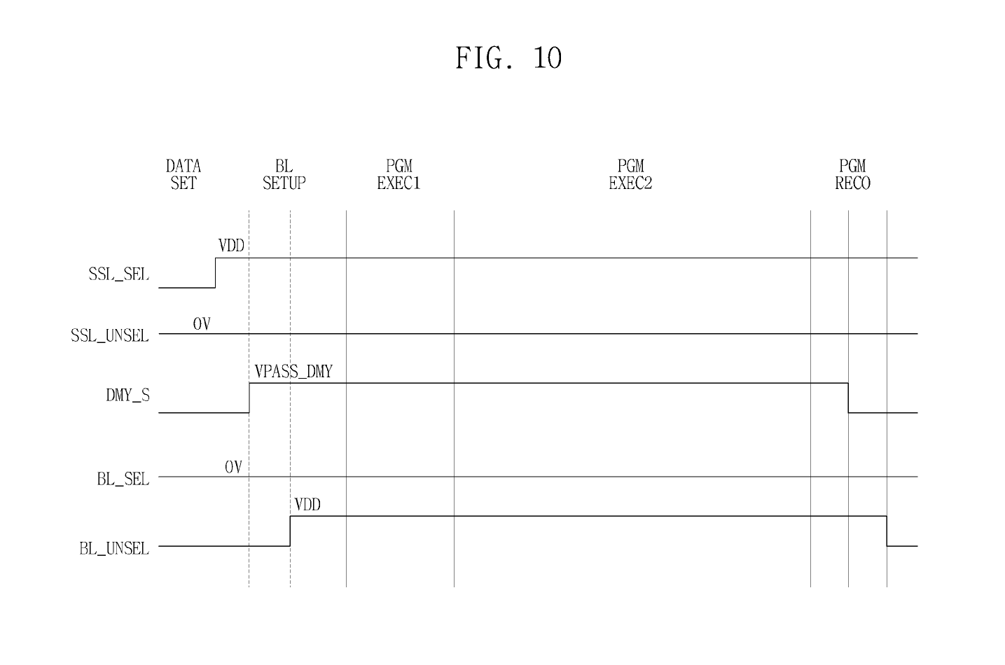

FIG. 9 is a diagram illustrating a hot carrier injection and charge trapping generated in a channel area between a dummy WL (DMY_S) adjacent to a string select line SSL and the string select line SSL.

To precharge channels of memory transistors included in the string connected to the unselected BL BL_UNSEL, the dummy pass voltage VPASS_DMY may be applied to the dummy WL DMY_S adjacent to the SSL SSL using a method of FIG. 8. As shown in FIG. 9, when the dummy pass voltage VPASS_DMY is applied to the dummy WL DMY_S adjacent to the SSL SSL, a leakage current may be generated in the string connected to the selected BL BL_SEL. The hot carrier injection and charge trapping may be generated in a channel area between and the SSL SSL and the adjacent dummy WL DMY_S and included in a string connected to the selected SSL SSL_SEL. The reason for this is that a voltage is applied to the dummy WL DMY_S adjacent to the SSL SSL before the string select transistor is fully turned on, an electric potential of channels of memory transistors connected to the dummy WL DMY_S is increased, and the condition for hot carrier injection is set in a moment.

FIG. 10 is a timing diagram illustrating an example of a program operation of a NAND-type flash memory device, according to another embodiment of the inventive concept. In the method of FIG. 10, time points of applying voltages to the selected SSL SSL_SEL, the dummy WL DMY_S and the unselected BL BL_UNSEL are set differently, and therefore hot carriers may not be generated near channels of memory transistors connected to the dummy WL DMY_S.

Referring to FIG. 10, the supply voltage V_{DD} may first be applied to the selected SSL SSL_SEL, next, a dummy pass voltage VPASS_DMY may be applied to the dummy WL DMY_S, and last, the supply voltage V_{DD} may be applied to the unselected BL BL_UNSEL. In this case, the NAND-type flash memory device 100 may turn on memory transistors connected to the dummy WL DMY_S after string select transistors connected to the selected SSL SSL_SEL are fully turned on. Therefore, the NAND-type flash memory device 100 may eliminate the cause of generation of hot carrier, and then apply the supply voltage V_{DD} to the unselected BL BL_UNSEL to stably perform a precharge operation.

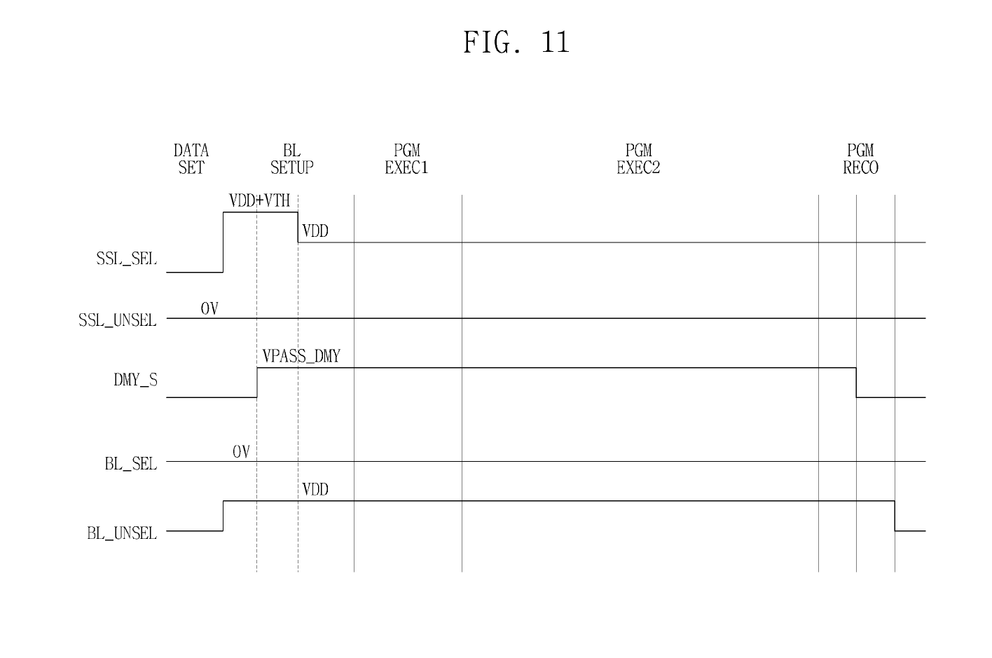

FIG. 11 is a timing diagram illustrating an example of a program operation of a NAND-type flash memory device, according to still another embodiment of the inventive concept.

Referring to FIG. 11, in the method of programming the NAND-type flash memory device, 0 V may be applied to the selected SSL SSL_SEL. Then, a voltage having a voltage greater than or equal to the supply voltage V_{DD} (V_{DD}+VTH_SSL) may be applied to the selected SSL SSL_SEL, and after a certain time the supply voltage V_{DD} may be applied to the selected SSL SSL_SEL. The dummy pass voltage VPASS_DMY may be applied to the dummy WL DMY_S while the voltage greater than or equal to the supply voltage V_{DD} (V_{DD} +VTH_SSL) is applied to the selected SSL SSL_SEL. Therefore, the hot carrier injection is not generated. Here, VTH_SSL denotes a threshold voltage of a string select transistor connected to a SSL. The dummy pass voltage VPASS_DMY may be applied to the dummy WL DMY_S at least 1 μs after the voltage greater than or equal to the supply voltage V_{DD} (V_{DD}+VTH_SSL) is applied to the selected SSL SSL_SEL. A voltage of V_{DD} may be applied to the unselected BL BL_UNSEL at the same time as a voltage having the voltage greater than or equal to the supply voltage V_{DD} (V_{DD} VTH_SSL) is applied to the selected SSL SSL_SEL. In the program method of FIG. 11, a voltage having a voltage greater than or equal to the supply voltage V_{DD} (V_{DD} VTH_SSL) is applied to the selected SSL SSL_SEL, and therefore string select transistors connected to the selected SSL SSL_SEL maintain an on state and the voltage of the unselected BL BL_UNSEL may be transferred to channels of the string select transistors. When the voltage of the unselected BL BL_UNSEL is transferred to the channel of a string select transistor, the voltage applied to the selected SSL SSL_SEL may be lowered to the supply voltage V_{DD}.

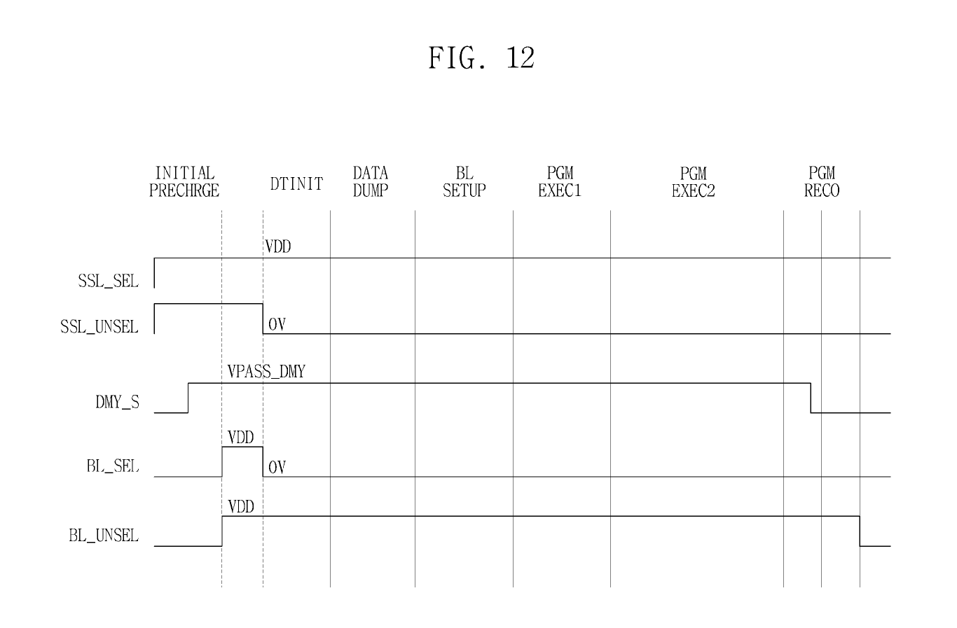

FIG. 12 is a timing diagram illustrating an example of a program operation of a NAND-type flash memory device, according to yet another embodiment of the inventive concept.

The method of programming shown in FIG. 12 may precharge the channels of memory transistors included in the string connected to the unselected SSL SSL_UNSEL using an operation mode of unselected string initial precharge (USIP) in addition to the method of FIG. 10. The process of programming may include an initial precharge, a data initializing DTINIT, a data dump DATA DUMP, a BL setup BL SETUP, a first program execution PGM EXEC1, a second program execution PGM EXEC2, and a program recover PGM RECO. Referring to FIG. 12, during the initial precharge a high voltage, e.g. V_{DD}, may be applied to the unselected SSL SSL_UNSEL. When the initial precharge is completed, a voltage of 0 V may be applied to the unselected SSL SSL_UNSEL. Further, the supply voltage V_{DD} may be applied to the selected BL BL_SEL during the initial precharge, and the voltage of 0 V may be applied when the initial precharge is completed. During the program process, the supply voltage V_{DD} may be applied to the unselected BL BL_UNSEL. The dummy pass voltage VPASS_DMY having a voltage in a range between 0 V to the pass voltage V_{PASS} may be applied to the dummy WL DMY_S during the program process. The supply voltage V_{DD} may be applied to the selected SSL SSL_SEL, and next the dummy pass voltage VPASS_DMY may be applied to the dummy WL DMY_S, and then the supply voltage V_{DD} may be applied to the unselected BL BL_UNSEL.

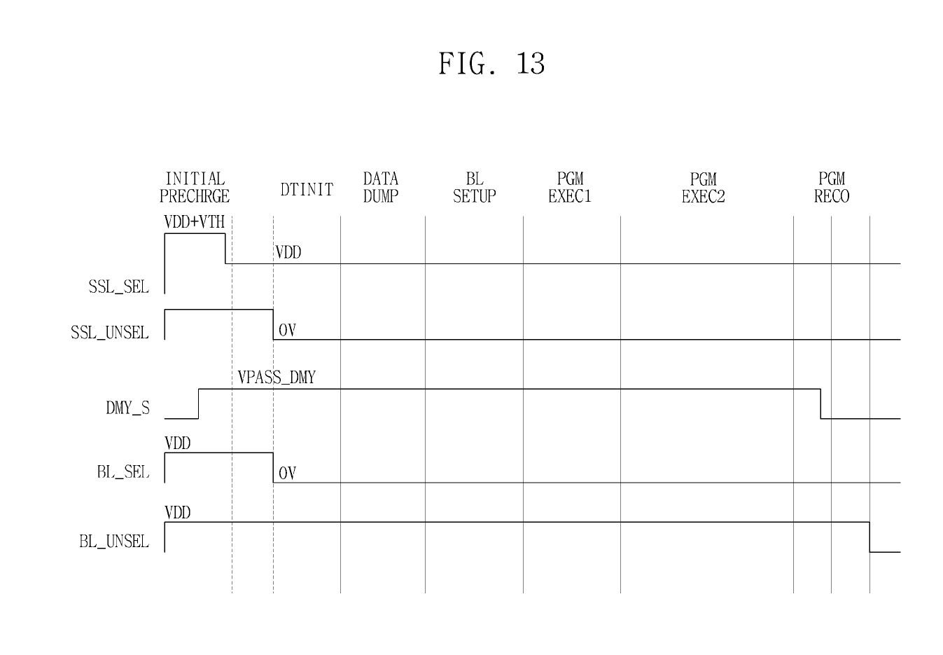

FIG. 13 is a timing diagram illustrating an example of a program operation of a NAND-type flash memory device, according to yet another embodiment of the inventive concept.

The method of programming shown in FIG. 13 may precharge the channels of memory transistors included in the string connected to the unselected SSL SSL_UNSEL using an operation mode of unselected string initial precharge (USIP) in addition to the method of FIG. 11. Referring to FIG. 13, during the initial precharge a high voltage, e.g. V_{DD}, may be applied to the unselected SSL SSL_UNSEL. When the initial precharge is completed, a voltage of 0 V may be applied to the unselected SSL SSL_UNSEL. The voltage having a voltage greater than or equal to the supply voltage V_{DD} (V_{DD}+VTH_SSL) may be applied to the selected SSL SSL_SEL, and after a certain time the supply voltage V_{DD} may be applied to the selected SSL SSL_SEL, and therefore the hot carrier injection is not generated near the channels of memory transistors connected to the dummy WL DMY_S. Here, VTH_SSL denotes a threshold voltage of a string select transistor connected to a SSL. A voltage of V_{DD} may be applied to the unselected BL BL_UNSEL at the same time as the voltage having a voltage greater than or equal to the supply voltage V_{DD} (V_{DD}+VTH_SSL) is applied to the selected SSL SSL_SEL, and 0 V may be applied to the selected BL BL_SEL when the initial precharge is completed. In the program method of FIG. 13, a voltage having a voltage greater than or equal to the supply voltage V_{DD} (V_{DD}+VTH_SSL) is applied to the selected SSL SSL_SEL, and therefore string select transistors connected to the selected SSL SSL_SEL maintain an on state, and the voltage of the unselected BL BL_UNSEL may be transferred to channels of the string select transistors, and then the voltage applied to the selected SSL SSL_SEL may be lowered to the supply voltage V_{DD}. During the program process, the supply voltage V_{DD} may be applied to the unselected BL BL_UNSEL. The dummy pass voltage VPASS_DMY having a voltage greater than 0 V and less than the pass voltage V_{PASS} may be applied to the dummy WL DMY_S during the program process. The supply voltage V_{DD} may be applied to the selected SSL SSL_SEL, and then the dummy pass voltage VPASS_DMY may be applied to the dummy WL DMY_S.

When the program methods of FIGS. 12 and 13 are used, the precharge for a program inhibit operation may be performed when voltages applied to the SSL/BL have values of V_{DD}/V_{DD}, 0 V/V_{DD}, or 0 V/0 V even when the threshold voltage of memory transistors connected to the dummy WL DMY_S is greater than the threshold voltage of memory transistors connected to a normal WL.

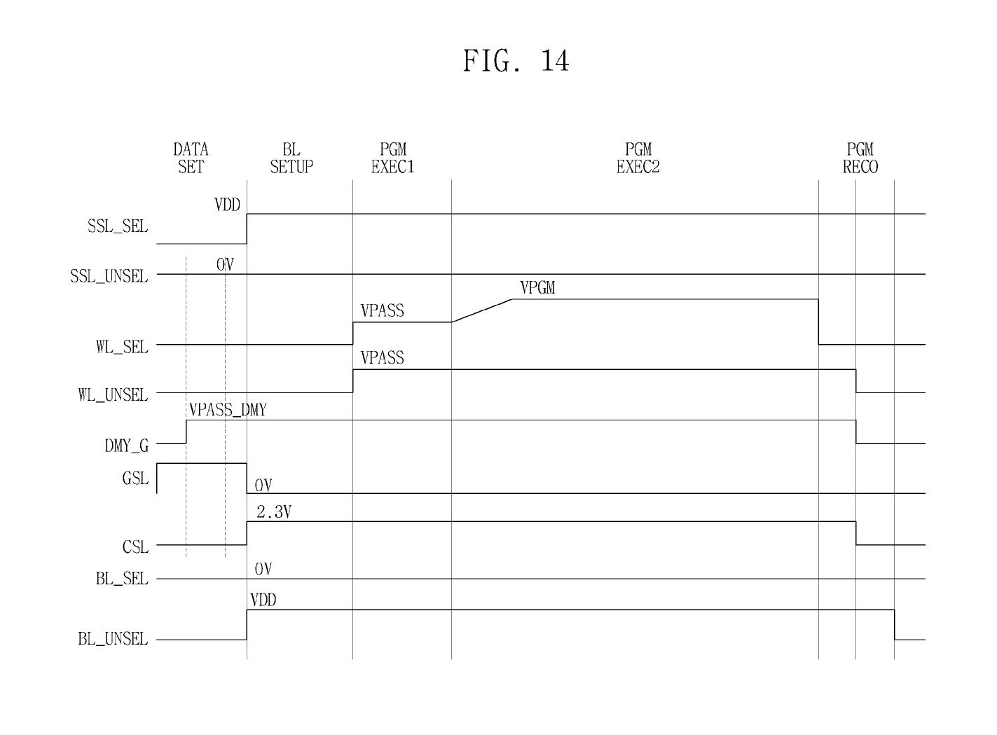

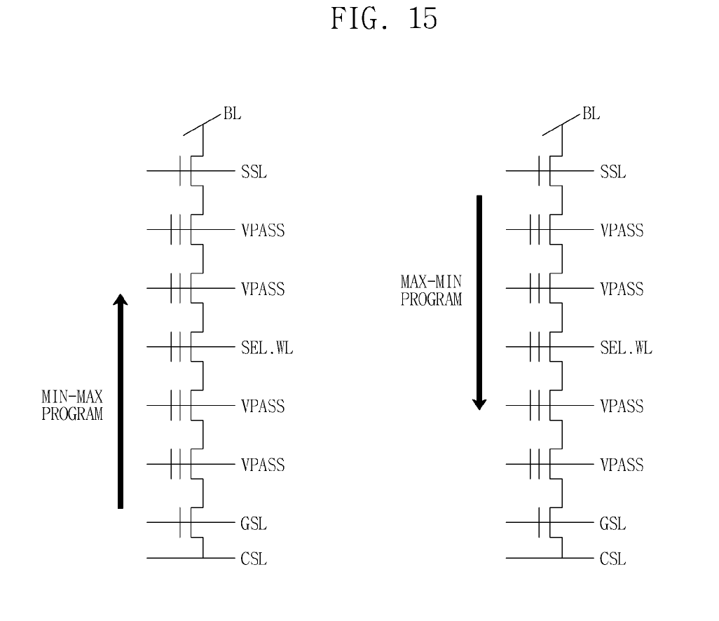

FIG. 14 is a timing diagram illustrating an example of a program operation of a NAND-type flash memory device, according to yet another embodiment of the inventive concept, and FIG. 15 is a circuit diagram illustrating two types of program modes that may apply to a NAND-type flash memory device, according to an embodiment of the inventive concept.

FIG. 14 is a timing diagram illustrating a method of precharging memory transistors of a string for which programming is inhibited using the ground select line GSL and the CSL CSL. The program method of FIG. 14 may be applied to a program of a MAX-min method in which the program is processed from the SSL SSL to the ground select line GSL. On the contrary, the program method of FIG. 8 may be applied to a program of a MIN-max method in which the program is processed from the ground select line GSL to the SSL SSL. In FIG. 15, the MAX-min and MIN-max methods of programming a NAND-type flash memory device are shown.

Referring to FIG. 14, during the data set DATA SET, a high voltage, e.g. V_{DD}, may be applied to the ground select line GSL, and 0 V may be applied to the ground select line GSL when the BL setup operation begins. The strings of a memory cell array may include a dummy WL DMY_G adjacent to the ground select line GSL. During the program process, the dummy pass voltage VPASS_DMY having a voltage in a range between 0 V to the pass voltage V_{PASS} may be applied to the dummy WL DMY_G adjacent to the ground select line GSL. The pass voltage V_{PASS} may be applied to the unselected WL WL_UNSEL during the first program execution PGM EXEC1 and the second program execution PGM EXEC2. The pass voltage V_{PASS} may be applied to the selected WL WL_SEL during the first program execution PGM EXEC1, and a program voltage VPGM may be applied to the selected WL WL_SEL during the second program execution PGM EXEC2. In the program method of FIG. 14, the ground select line GSL is first activated, and then the dummy pass voltage VPASS_DMY is applied to the dummy WL DMY_G. The supply voltage V_{DD} (e.g., 2.3V) is applied to the CSL, and the ground select line GSL is deactivated. Therefore, a voltage precharged in the BL BL may be transferred to channels of memory transistors connected to the dummy WL DMY_G.

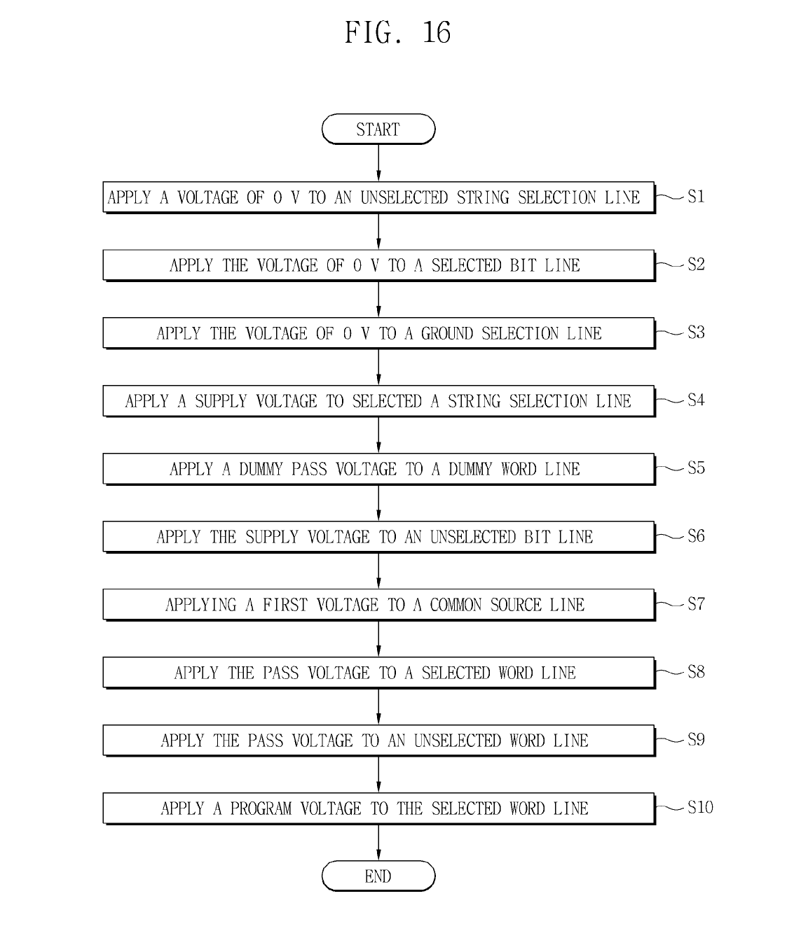

FIGS. 16 to 21 are flowcharts illustrating methods of programming a NAND-type flash memory device, according to embodiments of the inventive concept.

The NAND-type flash memory device may include a memory cell array. The memory cell array may include a plurality of cell strings connected to corresponding BLs, and each of the cell strings has a string select transistor, a ground select transistor having a first output terminal connected to a CSL, and a plurality of cell transistors. The memory cell array may include a plurality of WLs arranged parallel and perpendicular to the BLs.

Referring to FIG. 16, a method of programming a NAND-type flash memory device may include the following operations, according to an embodiment: (1) applying a voltage of 0 V to an unselected SSL SSL_UNSEL (S1); (2) applying the voltage of 0 V to a selected BL BL_SEL (S2); (3) applying the voltage of 0 V to a ground select line GSL (S3); (4) applying a supply voltage V_{DD} to a selected SSL SSL_SEL (S4); (5) applying a dummy pass voltage VPASS_DMY having a voltage in a range between 0 V to a pass voltage V_{PASS} to a dummy WL DMY_S (S5); (6) applying the supply voltage V_{DD} to an unselected BL BL_UNSEL (S6); (7) applying a first voltage to a CSL CSL (S7); (8) applying the pass voltage V_{PASS} to a selected WL WL_SEL (S8); (9) applying the pass voltage V_{PASS} to an unselected WL WL_UNSEL (S9); and (10) applying a program voltage V_{PGM} to the selected WL WL_SEL (S10). In FIG. 16, the first voltage applied to the CSL CSL may be in a range of 0 V to the supply voltage V_{DD}.

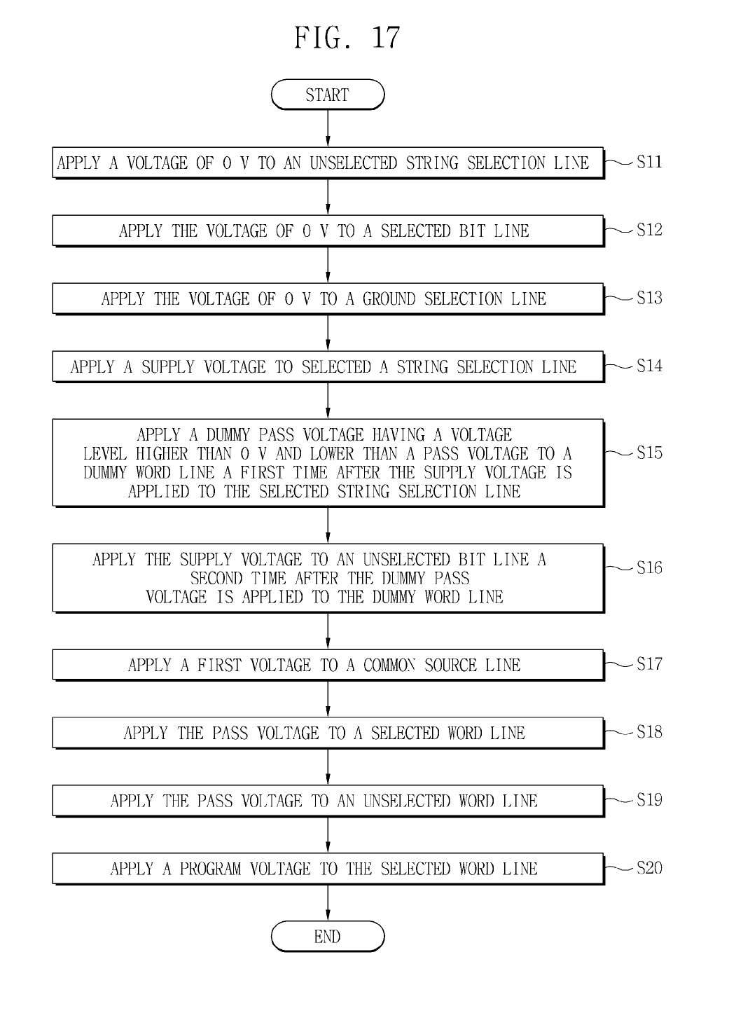

Referring to FIG. 17, a method of programming a NAND-type flash memory device may include the following operations, according to an embodiment: (1) applying a voltage of 0 V to an unselected SSL SSL_UNSEL (S11); (2) applying the voltage of 0 V to a selected BL BL_SEL (S12); (3) applying the voltage of 0 V to a ground select line GSL (S13); (4) applying a supply voltage V_{DD} to a selected SSL SSL_SEL (S14); (5) applying a dummy pass voltage VPASS_DMY having a voltage in a range between 0 V to a pass voltage V_{PASS} to a dummy WL DMY_S at a first time after the supply voltage V_{DD} is applied to the selected SSL SSL_SEL (S15); (6) applying the supply voltage V_{DD} to an unselected BL BL_UNSEL at a second time after the dummy pass voltage VPASS_DMY is applied to the dummy WL DMY_S (S16); (7) applying a first voltage to a CSL CSL (S17); (8) applying the pass voltage V_{PASS} to a selected WL WL_SEL (S18); (9) applying the pass voltage V_{PASS} to an unselected WL WL_UNSEL (S19); and (10) applying a program voltage V_{PGM} to the selected WL WL_SEL (S20). In FIG. 17, the first voltage applied to the CSL CSL may have a voltage in a range of 0 V to the supply voltage V_{DD}.

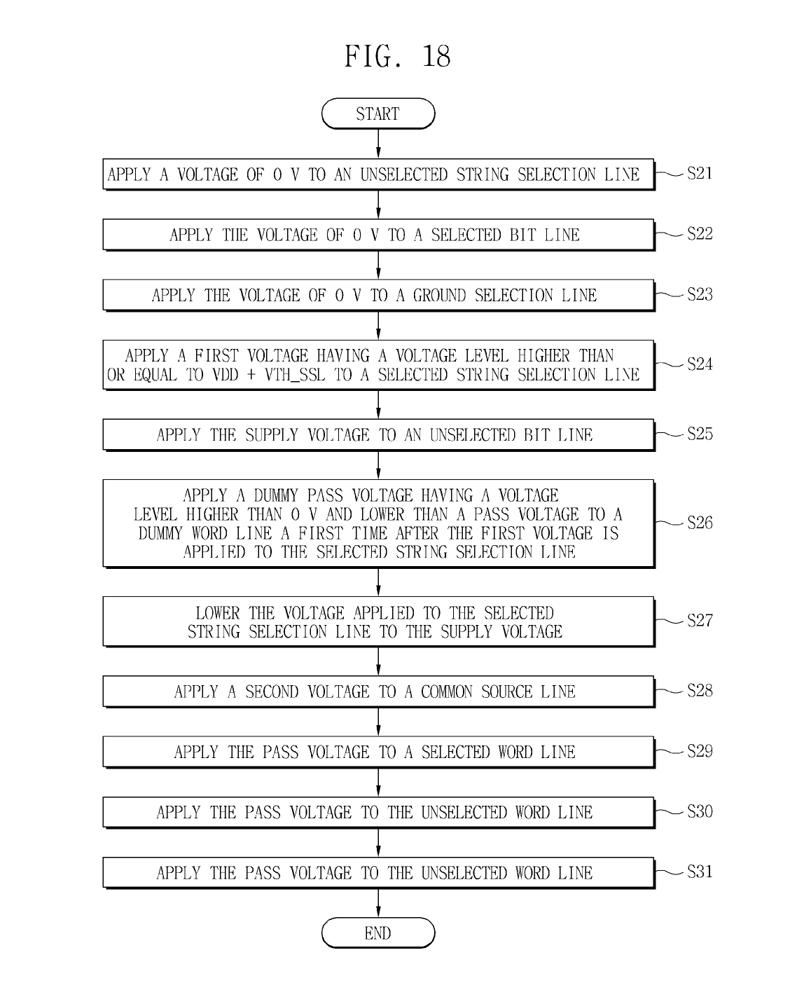

Referring to FIG. 18, a method of programming a NAND-type flash memory device may include the following operations, according to an embodiment: (1) applying a voltage of 0 V to an unselected SSL SSL_UNSEL (S21); (2) applying the voltage of 0 V to a selected BL BL_SEL (S22); (3) applying the voltage of 0 V to a ground select line GSL (S23); (4) applying a first voltage having a voltage greater than or equal to (V_{DD}+VTH_SSL) to a selected SSL SSL_SEL (S24); (5) applying a supply voltage V_{DD} to an unselected BL BL_UNSEL (S25); (6) applying a dummy pass voltage VPASS_DMY having a voltage in a range between 0 V to a pass voltage V_{PASS} to a dummy WL DMY_S at a first time after the first voltage is applied to the selected SSL SSL_SEL (S26); (7) decreasing the voltage applied to the selected SSL SSL_SEL to the supply voltage V_{DD} (S27); (8) applying a second voltage to a CSL CSL (S28); (9) applying the pass voltage V_{PASS} to a selected WL WL_SEL (S29); (10) applying the pass voltage V_{PASS} to an unselected WL WL_UNSEL (S30); and (11) applying a program voltage V_{PGM} to the selected WL WL_SEL (S31). In FIG. 18, the second voltage applied to the CSL CSL may have a voltage in a range of 0 V to the supply voltage V_{DD}.

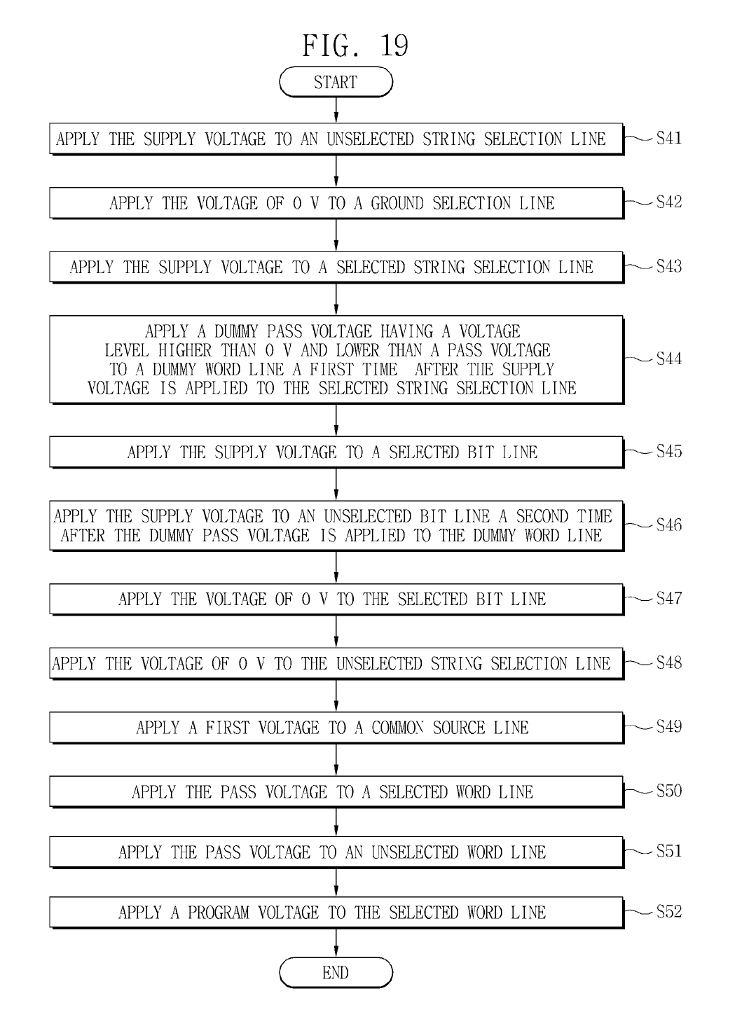

Referring to FIG. 19, a method of programming a NAND-type flash memory device may include the following operations, according to an embodiment: (1) applying a supply voltage V_{DD} to an unselected SSL SSL_UNSEL (S41); (2) applying the voltage of 0 V to a ground select line GSL (S42); (3) applying the supply voltage V_{DD} to a selected SSL SSL_SEL (S43); (4) applying a dummy pass voltage VPASS_DMY having a voltage in a range between 0 V to a pass voltage V_{PASS} to a dummy WL DMY_S at a first time after the supply voltage V_{DD} is applied to the selected SSL SSL_SEL (S44); (5) applying the supply voltage to a selected BL BL_SEL (S45); (6) applying the supply voltage V_{DD} to an unselected BL BL_UNSEL at a second time after the dummy pass voltage VPASS_DMY is applied to the dummy WL DMY_S (S46); (7) applying the voltage of 0 V to the selected BL BL_SEL (S47); (8) applying the voltage of 0 V to the unselected SSL SSL_UNSEL (S48); (9) applying a first voltage to a CSL CSL (S49); (10) applying the pass voltage V_{PASS} to a selected WL WL_SEL (S50); (11) applying the pass voltage V_{PASS} to an unselected WL WL_UNSEL (S51); and (12) applying a program voltage _{VPGM} to the selected WL WL_SEL (S52). In FIG. 19, the first voltage applied to the CSL CSL may have a voltage in a range of 0 V to the supply voltage V_{DD}.

Referring to FIG. 20, a method of programming a NAND-type flash memory device may include the following operations, according to an embodiment: (1) applying a voltage of 0 V to a ground select line GSL (S61); (2) applying a first voltage having a voltage greater than or equal to (V_{DD}+VTH_SSL) to a selected SSL SSL_SEL (S62); (3) applying a supply voltage V_{DD} to an unselected SSL SSL_UNSEL (S63); (4) applying the supply voltage V_{DD} to an unselected BL BL_UNSEL (S64); (5) applying the supply voltage V_{DD} to a selected BL BL_SEL (S65); (6) applying a dummy pass voltage VPASS_DMY having a voltage in a range between 0 V to a pass voltage V_{PASS} to a dummy WL DMY_S at a first time after the first voltage is applied to the selected SSL SSL_SEL (S66); (7) decreasing the voltage applied to the selected SSL SSL_SEL to the supply voltage V_{DD} (S67); (8) applying the voltage of 0 V to the unselected SSL SSL_UNSEL (S68); (9) applying the voltage of 0 V to the selected BL BL_SEL (S69); (10) applying a second voltage to a CSL CSL (S70); (11) applying the pass voltage V_{PASS} to a selected WL WL_SEL (S71); (12) applying the pass voltage V_{PASS} to an unselected WL WL_UNSEL (S72); and (13) applying a program voltage V_{PGM} to the selected WL WL_SEL (S73). In FIG. 20, the second voltage applied to the CSL CSL may have a voltage in a range of 0 V to the supply voltage V_{DD}.

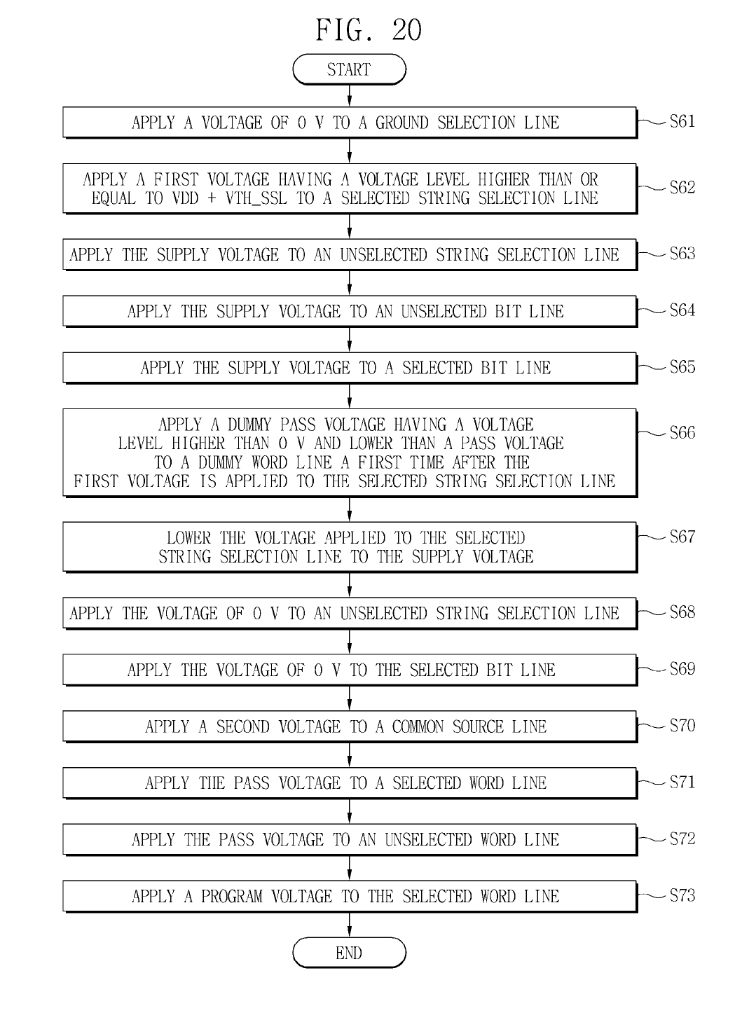

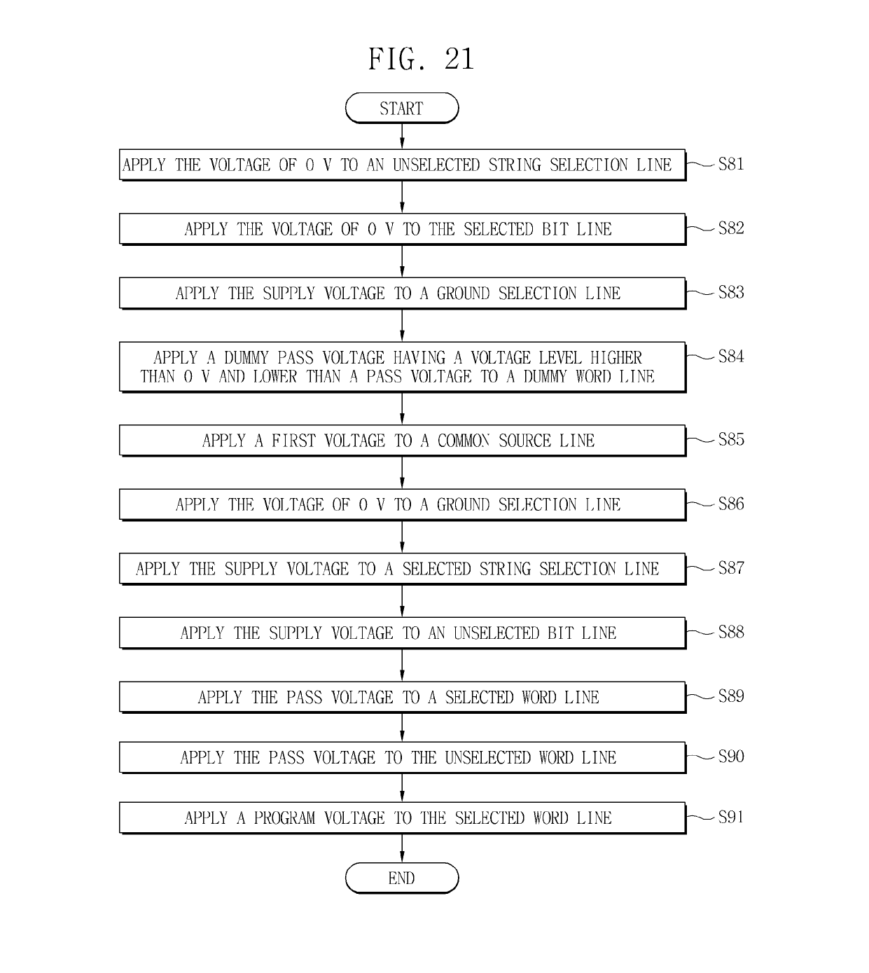

Referring to FIG. 21, a method of programming a NAND-type flash memory device may include the following operations, according to an embodiment: (1) applying the voltage of 0 V to an unselected SSL SSL_UNSEL (S81); (2) applying the voltage of 0 V to a selected BL BL_SEL (S82); (3) applying a supply voltage V_{DD} to a ground select line GSL (S83); (4) applying a dummy pass voltage VPASS_DMY having a voltage in a range between 0 V to a pass voltage V_{PASS} to a dummy WL DMY_S (S84); (5) applying a first voltage to a CSL CSL (S85); (6) applying the voltage of 0 V to a ground select line GSL (S86); (7) applying the supply voltage V_{DD} to a selected SSL SSL_SEL (S87); (8) applying the supply voltage V_{DD} to an unselected BL BL_UNSEL (S88); (9) applying the pass voltage V_{PASS} to a selected WL WL_SEL (S89); (10) applying the pass voltage V_{PASS} to an unselected WL WL_UNSEL (S90); and (11) applying a program voltage V_{PGM} to the selected WL WL_SEL (S91). In FIG. 21, the first voltage applied to the CSL CSL may have a voltage in a range of 0 V to the supply voltage V_{DD}.

FIG. 22 is a perspective view of a structure of a NAND-type flash memory device 1, according to an embodiment of the inventive concept. The NAND-type flash memory device shown in FIG. 22 may be a VNAND flash memory device, for example.

Referring to FIG. 22, the NAND-type flash memory device 1 includes a cell region 2 including memory cells, and a peripheral region 3 including a peripheral circuit for operating the memory cells.

In the cell region 2, a plurality of control gates 27 are vertically stacked on a semiconductor substrate 20 in a Z direction and have an X-Y plane in a plate type, a lower select gate 23 is disposed below the plurality of control gates 27, a plurality of upper select gates 25 are disposed on the plurality of control gates 27, a plurality of BLs 21 are stacked on an upper select gate 25 and extend in a Y direction, and a plurality of active pillars 29 vertically extend in the Z direction on the semiconductor substrate 20. Each of the plurality of active pillars 29 extends from the semiconductor substrate 20 to the plurality of BLs while passing through the upper and lower select gates 25 and 23 and the plurality of control gates 27, and thus may be used as a channel. The semiconductor substrate 20 may be a P-type silicon substrate. The plurality of active pillars 29 may be formed of a material used to form the semiconductor substrate 20, and may be the same conductive type as the semiconductor substrate 20. The semiconductor substrate 20 may include a source region 20s that is a different conductive type, e.g., an N-type, from that of the semiconductor substrate 20.

The peripheral region 3 may include a plurality of first lines 32 for connecting the plurality of upper select gates 25 to an upper select line driving circuit (not shown), a plurality of second lines 33 for connecting the plurality of control gates 27 to a WL driving circuit (not shown), and a third line 34 for connecting the lower select gate 23 to a lower select line driving circuit (not shown). A plurality of first contact plugs 32a are provided between the plurality of first lines 32 and the plurality of upper select gates 25 to electrically connect the plurality of first lines 32 and the plurality of upper select gates 25. A plurality of second contact plugs 33a are provided between the plurality of second lines 33 and the plurality of control gates 27 to electrically connect the plurality of second lines 33 and the plurality of control gates 27. A third contact plug 34a may be provided between the third line 34 and the lower select gate 23 to electrically connect the third line 34 and the lower select gate 23.

One of the lower select gate 23 and the upper select gate 25 may have a plate type formed in the X-Y plane, and the other may have a separated line shape extending in an X direction. As another example, the lower select gate 23 and the upper select gate 25 may each have a separated line shape extending in the X direction. In the embodiment, the lower select gate 23 may have a plate shape formed in the X-Y plane, and the upper select gate 25 may have a separated line shape extending in the X direction.

The gates 23, 25, and 27 may be provided in a stepwise fashion. Owing to the stepwise fashion, a plurality of WL pads 37 configured to provide regions in which a plurality of third contact plugs 34a are connected to the plurality of control gates 27, respectively, may be defined. In the disclosure, the plurality of WL pads 37 are not covered with an upper control gate 27 among the plurality of control gates 27 and may thus be defined as an exposed surface. The stepwise fashion may be realized at the left and right sides of the plurality of control gates 27.

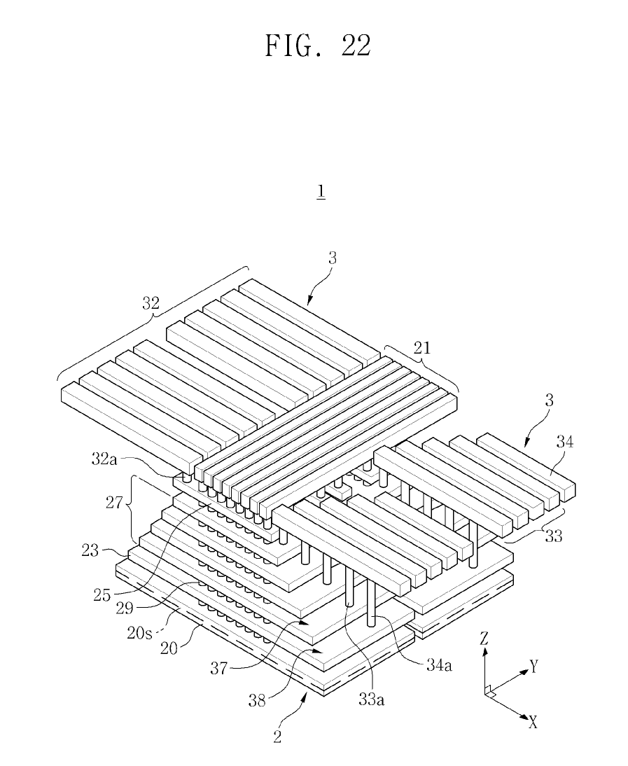

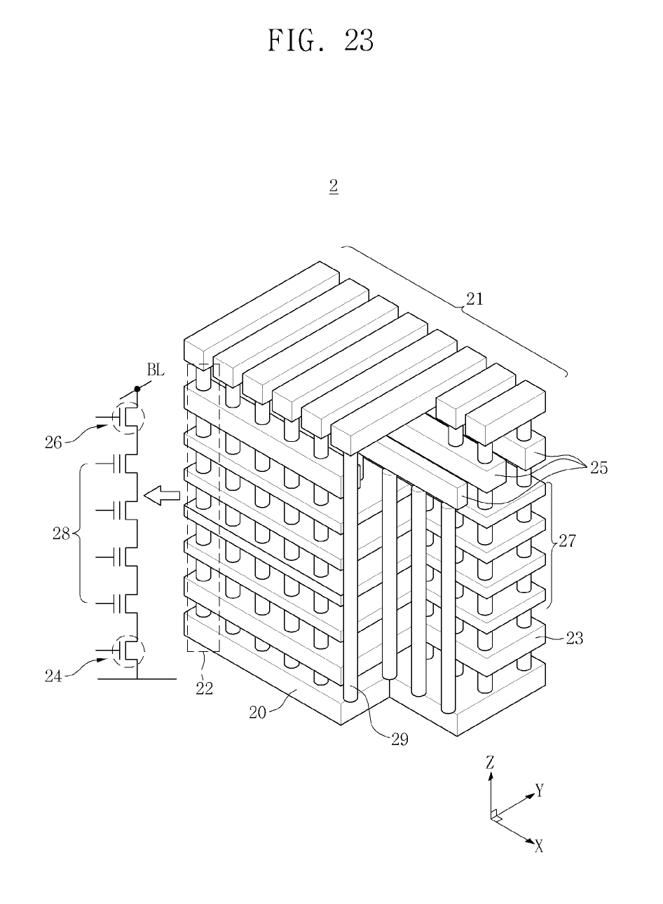

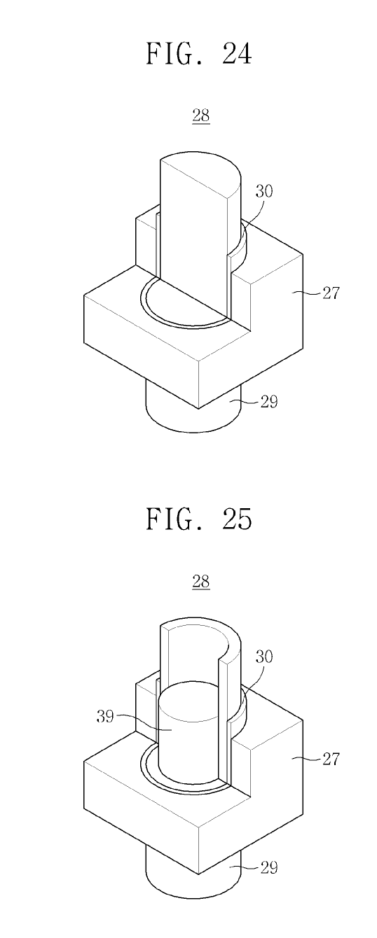

FIG. 23 is a perspective view of a cell region of the NAND-type flash memory device 1 illustrated in FIG. 22, according to an embodiment of the inventive concept. FIGS. 24 and 25 are perspective views illustrating examples of a cell transistor included in the cell region of the FIG. 23, according to embodiments of the inventive concept.

Referring to FIG. 23, an active pillar 29 and a plurality of control gates 27 define a plurality of memory transistors 28. The active pillar 29 and a lower select gate 23 define a lower select transistor 24. The active pillar 29 and upper select gates 25 define an upper select transistor 26. In the embodiment, the nonvolatile memory device 1 may be a NAND flash memory device in which the plurality of memory transistors 28 and the upper and lower select transistors 26 and 24 formed in one active pillar 29 are connected in series to form one cell string 22. In the embodiment, one cell string 22 includes four memory transistors 28, but the number of memory transistors 28 included in one cell string 22 is not limited to four and may be an arbitrary number, e.g., eight, sixteen, or thirty two, according to a memory capacity. The plurality of active pillars 29 may each have a cylindrical shape, a cross-section of which has a circular shape, but is not limited thereto and may have a square pillar shape, a cross-section of which has a rectangular shape, or other configurations, for example.

The plurality of memory transistors 28 and the upper and lower select transistors 26 and 24 may be depletion transistors, for example, that do not include a source/drain region in the plurality of active pillars 29. As another example, the plurality of memory transistors 28 and the upper and lower select transistors 26 and 24 may be enhancement transistors that include a source/drain region in the plurality of active pillars 29.

The plurality of active pillars 29 may each have an axis in the Z direction passing through the plurality of control gates 27. Thus, intersections of the plurality of control gates 27 and the plurality of active pillars 29 may be distributed three-dimensionally. The plurality of memory transistors 28 according to the embodiment may be formed at the intersections that are distributed three-dimensionally.

Referring to FIG. 24, a gate insulating film 30 including a charge storing film may be interposed between an active pillar 29 and a control gate 27. The charge storing film may include an insulating film capable of trapping electric charges. For example, when the gate insulating film 30 is an ONO film, in which a silicon oxide film, a silicon nitride film (or a silicon oxynitride film) and a silicon oxide film are stacked, electric charges may be trapped and held in the silicon nitride film (or the silicon oxynitride film). As another example, the charge storing film may include a floating gate formed of a conductor.

Referring to FIG. 25, active pillars 29 may each have a hollow, curved (macaroni) shape having an insulator 39 therein. The insulator 39 may have a pillar shape. Since the insulator 39 occupies the active pillar 29, the thickness of the active pillar 29 may be less than that of the active pillar 29 illustrated in FIG. 9, thereby reducing trap sites of carriers.

Referring back to FIG. 23, the upper and lower select transistors 26 and 24 may have a structure as illustrated in FIG. 6 or 7. A gate insulating film 30 included in the upper and lower select transistors 26 and 24 may be formed of a silicon oxide film or a silicon nitride film.

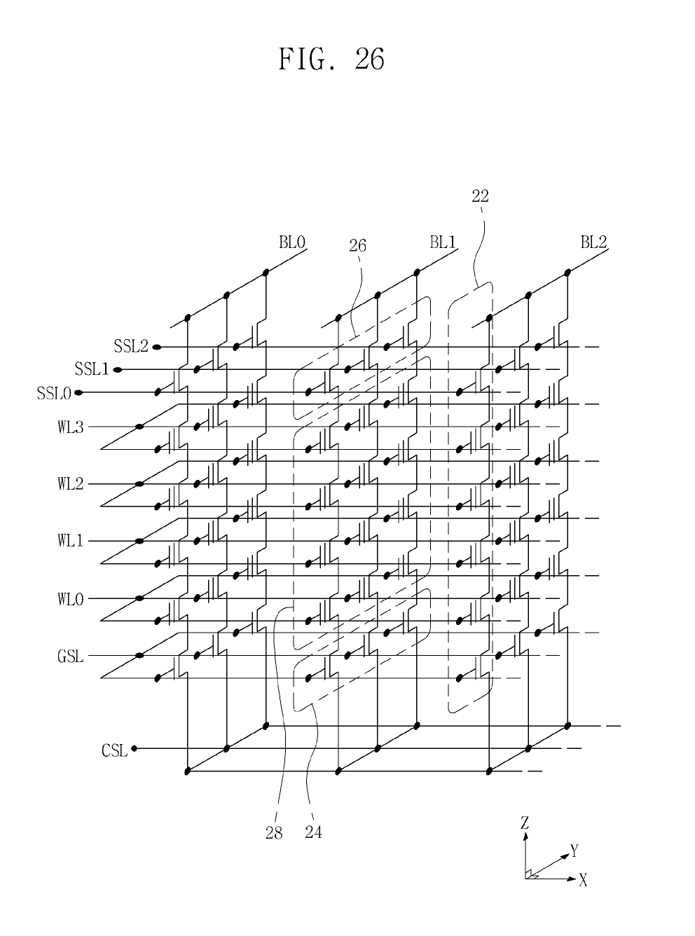

FIG. 26 is a circuit diagram of an example of a memory cell array of the NAND-type flash memory device illustrated in FIG. 22, according to an embodiment of the inventive concept.

Referring to FIGS. 26 and 22, in the nonvolatile memory device 1, the plurality of control gates 27 correspond to a plurality of WLs WL0 to WL3, the plurality of upper select gates 25 correspond to a plurality of SSLs SSL0 to SSL2, the lower select gate 23 corresponds to a ground select line GSL, and the source region 20s of the semiconductor substrate 20 corresponds to a CSL CSL. A plurality of cell strings 22 may be connected to each of the plurality of BLs BL0 to BL2.

Each of the plurality of control gates 27 may have a flat plate type structure that extends two-dimensionally. Thus, each of the plurality of WLs WL0 to WL3 may have a planar structure and may be substantially perpendicular to the plurality of cell strings 22. In the plurality of WLs WL0 to WL3, the plurality of memory transistors 28 may be distributed three-dimensionally.

Since the upper select gate 25 may form a separated wire structure extending in an X direction, the plurality of SSLs SSL0 to SSL2 may be disposed to cross under the plurality of BLs BL0 to BL2 in the X direction. The plurality of SSLs SSL0 to SSL2 disposed in a Y direction are electrically connected to the plurality of BLs BL0 to BL2 disposed in the X direction, respectively. Accordingly, one cell string 22 may be individually selected among the plurality of cell strings 22.

Since the lower select gate 23 may have a flat plate type structure that extends two-dimensionally, the ground select line GSL may have a planar structure and may be substantially perpendicular to the plurality of cell strings 22. The ground select line GSL may control an electrical connection between the plurality of active pillars 29 and the semiconductor substrate 20.

A program operation of the nonvolatile memory device 1 according to the embodiment may be performed by setting a voltage difference between a selected WL and the active pillar 29 and injecting electric charges into a charge storing film (not shown). For example, the program operation may be performed based on Fowler-Nordheim tunneling by applying a program voltage Vprg to the selected WL, so that electrons may be injected into the charge storing film included in a memory transistor 28 belonging to a WL, which is to be programmed, from the active pillar 29. The program voltage Vprg applied to the selected WL may program a memory transistor 28 belonging to a non-selected WL. To prevent this, a boosting technique may be used not to perform undesired programming.

In a read operation of the nonvolatile memory device 1, a voltage of a WL connected to a memory transistor 28 to be read is set to be, for example, zero and a read voltage Vread is applied to the other WLs. As a result, whether a BL is charged with electric current is determined according to whether a threshold voltage Vₜₕ of the memory transistor 28 to be read is less than or greater than 0 volts. Thus, data may be read from the memory transistor 28 by sensing the electric current flowing through the BL.

An erase operation of the nonvolatile memory device 1 may be performed in units of blocks by using gate-induced drain leakage (GIDL) current. For example, electric potentials of the plurality of active pillars 29 are increased by applying an erase voltage Vₑᵣₐₛₑ to a selected BL and the semiconductor substrate 20 of FIG. 7. In this case, the electric potentials of the plurality of active pillars 29 may be slightly delayed and increased. An increase in the electric potentials of the plurality of active pillars 29 causes the GIDL current to be generated by a terminal of the lower select gate 23, and electrons and holes generated from the GIDL current are discharged to the semiconductor substrate 20 and the plurality of active pillars 29, respectively. Thus, an electric potential that is substantially the same as the erase voltage Vₑᵣₐₛₑ may be delivered to a channel of the memory transistor 28, i.e., the plurality of active pillars 29. In this case, when an electric potential of the selected WLs is set to be 0 volts, electrons accumulated in the memory transistors 28 are discharged out of the memory transistors 28, thereby erasing data from the memory transistors 28. WLs connected to the non-selected blocks may be floated not to perform the erase operation on the non-selected blocks.

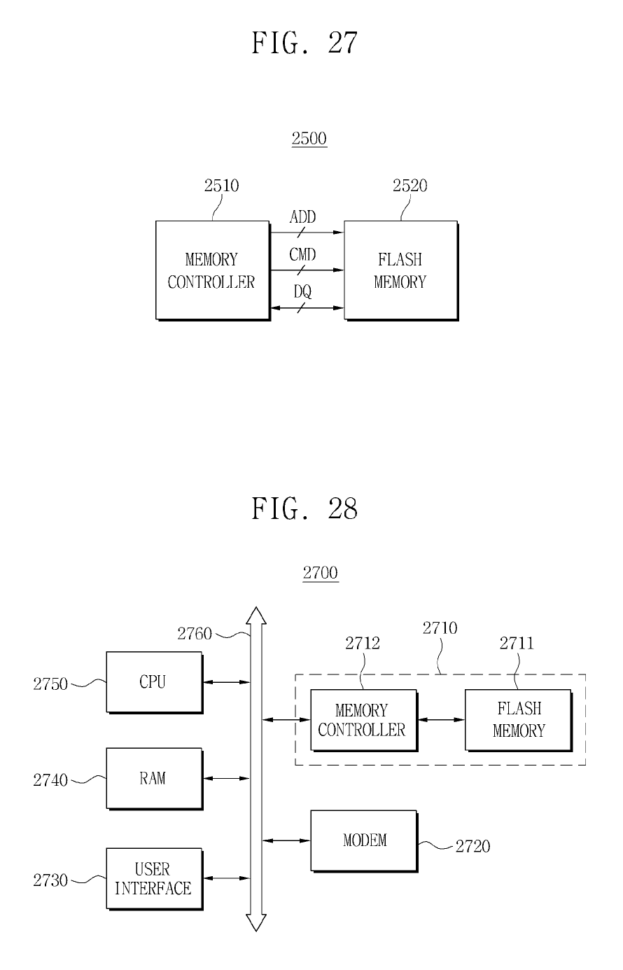

FIG. 27 is a block diagram of a memory system 2500 including a NAND-type flash memory device, according to embodiments of the inventive concept.

Referring to FIG. 27, the memory system 2500 includes a memory controller 2510 and a flash memory 2520. The memory controller 2510 generates an address signal ADD and a command CMD, and provides the address signal ADD and the command CMD to the flash memory device 2520 via a bus. Data DQ is transmitted from the memory controller 2510 to the flash memory device 2520 or from the flash memory device 2520 to the memory controller 2510, via a bus.

The flash memory device 2520 may be a NAND-type flash memory device in accordance with embodiments of the inventive concept, and may apply the dummy pass voltage VPASS_DMY having a voltage in a range between 0 V to the pass voltage V_{PASS} to the dummy WL DMY_S during the program process, and therefore a voltage precharged in the BL may be transferred to channels of memory transistors connected to the dummy WL DMY_S. Further, in the flash memory device 2520, time points of applying voltages to the selected SSL SSL_SEL, the dummy WL DMY_S, and the unselected BL BL_UNSEL are set differently, and therefore precharging may be stably performed. Further, the flash memory device 2520 may apply a voltage having a voltage greater than or equal to (V_{DD} +VTH_SSL) to the selected SSL SSL_SEL during the BL setup, and therefore string select transistors connected to the selected SSL SSL_SEL maintain an on state and the voltage of the unselected BL BL_UNSEL may be transferred to channels of the string select transistors. Further, in the flash memory device 2520, the supply voltage V_{DD} is applied to the unselected SSL SSL_UNSEL during an initial precharge period before the BL setup period, and string select transistors connected to the unselected SSL SSL_UNSEL are turned on, therefore cell strings connected to the unselected SSL SSL_UNSEL may be safely precharged.

FIG. 28 is a block diagram of an information processing system 2700 including a NAND-type flash memory device, according to embodiments of the inventive concept.

Referring FIG. 28, the flash memory 2711 may be installed in a computer system 2700, e.g., a mobile apparatus or a desk-top computer. The computer system 2700 may include a memory system 2710, a modem 2720, a central processing unit (CPU) 2750, a RAM 2740, and a user interface 2730 which are electrically connected via a system bus 2760.

The memory system 2710 may include the flash memory 2711 and a memory controller 2712. The flash memory 2711 stores data processed by the CPU 2750 or data input from the outside.

The flash memory device 2711 may be a NAND-type flash memory device according to embodiments of the inventive concept, and may apply the dummy pass voltage VPASS_DMY having a voltage in a range between 0 V to the pass voltage V_{PASS} to the dummy WL DMY_S during the program process, and therefore a voltage precharged in the BL may be transferred to channels of memory transistors connected to the dummy WL DMY_S. Further, in the flash memory 2711, time points of applying voltages to the selected SSL SSL_SEL, the dummy WL DMY_S, and the unselected BL BL_UNSEL are set differently, and therefore precharge may be stably performed. Further, the flash memory 2711 may apply a voltage having a voltage greater than or equal to (V_{DD} +VTH_SSL) to the selected SSL SSL_SEL during the BL setup, and therefore string select transistors connected to the selected SSL SSL_SEL maintain an on state and the voltage of the unselected BL BL_UNSEL may be transferred to channels of the string select transistors. Further, in the flash memory 2711, the supply voltage V_{DD} is applied to the unselected SSL SSL_UNSEL during an initial precharge period before the BL setup period, and string select transistors connected to the unselected SSL SSL_UNSEL are turned on, therefore cell strings connected to the unselected SSL SSL_UNSEL may be stably precharged.

Although not shown in FIG. 28, it would be apparent to one of ordinary skill in the art that the information processing system 2700 may further include an application chipset, a camera image processor, an I/O device, and so on.

The dummy WL of the NAND-type flash memory device in accordance with embodiments of the inventive concept may be used as a normal WL when the normal WL has defects.

The NAND-type flash memory device in accordance with embodiments of the inventive concepts may apply the dummy pass voltage VPASS_DMY having a voltage in a range between 0 V to the pass voltage V_{PASS} to the dummy WL DMY_S during the programming process, and therefore a voltage precharged in the BL may be transferred to channels of memory transistors connected to the dummy WL DMY_S. Further, in the NAND-type flash memory device in accordance with embodiments of the inventive concept, time points of applying voltages to the selected SSL SSL_SEL, the dummy WL DMY_S, and the unselected BL BL_UNSEL may be set differently, and therefore precharging may be stably performed. Further, the NAND-type flash memory device in accordance with the embodiment of the inventive concept may apply a voltage having a voltage greater than or equal to (V_{DD}+VTH_SSL) to the selected SSL SSL_SEL during the BL setup, and therefore string select transistors connected to the selected SSL SSL_SEL maintain an on state and the voltage of the unselected BL BL_UNSEL may be transferred to channels of the string select transistors. Further, in the NAND-type flash memory device in accordance with embodiments of the inventive concept, the supply voltage V_{DD} is applied to the unselected SSL SSL_UNSEL during an initial precharge period before the BL setup period, and string select transistors connected to the unselected SSL SSL_UNSEL are turned on. Therefore, cell strings connected to the unselected SSL SSL_UNSEL may be stably precharged.

Embodiments of the inventive concept may be applied to a semiconductor integrated circuit, and particularly, to a non-volatile memory device and a memory system including the non-volatile memory device.

The foregoing is illustrative of embodiments and is not to be construed as limiting thereof. That is, while the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. A method of programming a NAND-type flash memory device, the method comprising:
applying the supply voltage to a selected string select line;
applying a dummy pass voltage to a dummy word line, the dumpy pass voltage being in a range between 0 V to a pass voltage;
applying a supply voltage to an unselected bit line;
applying a voltage of 0 V to a selected bit line;
applying the pass voltage to a selected word line;
applying the pass voltage to an unselected word line; and
applying a program voltage to the selected word line.

2. The method of claim 1, further comprising:
initially applying the voltage of 0V to the unselected bit line.

3. The method of claim 1, further comprising:
applying the voltage of 0 V to a ground select line; and
applying a first voltage to a common source line, the first voltage being greater than 0 V and less than or equal to the supply voltage.

4. The method of claim 1, further comprising:
applying the supply voltage a ground select line; and
then applying the voltage of 0 V to the ground select line.

5. The method of claim 1, further comprising:
applying a voltage of 0 V to an unselected string select line.

6. The method of claim 1, wherein, in a program mode, time points of applying voltages to the selected string select line, the dummy word line and the unselected bit line are different.

7. The method of claim 1, wherein, in a program mode, the supply voltage is applied to the selected string select line, then after a first time interval, the dummy pass voltage is applied to the dummy word line, and then after a second time interval, the supply voltage is applied to the unselected bit line.

8. The method of claim 7, wherein each of the first time and the second time intervals is at least 1 μs.

9. The method of claim 1, wherein, in a program mode, a first voltage having a voltage greater than or equal to the supply voltage added to a threshold voltage of a string select transistor is applied to the selected string select line during a bit line setup period, and then after a first time interval, a voltage applied to the selected string select line is lowered to the supply voltage.

10. The method of claim 9, wherein, in the program mode, the first voltage is applied to the selected string select line, and then after a second time interval, the dummy pass voltage is applied to the dummy word line.

11. The method of claim 10, wherein the second time interval is at least 1 μs.

12. The method of claim 9, wherein, in the program mode, the supply voltage is applied to the unselected bit line when the first voltage is applied to the selected string select line.

13. A method of programming a NAND-type flash memory device, the method comprising:
applying a supply voltage to an unselected string select line;
applying the supply voltage to a selected string select line;
applying a dummy pass voltage to a dummy word line, the dumpy pass voltage being in a range between 0 V to a pass voltage;
applying the supply voltage to a selected bit line;
applying the supply voltage to an unselected bit line; and
applying a voltage of 0 V to the selected bit line.

14. The method of claim 13, wherein, in a program mode, the supply voltage is applied to the unselected string select line during an initial precharge period.

15. The method of claim 13, wherein, in a program mode, the supply voltage is applied to the selected string select line, then after a first time interval, the dummy pass voltage is applied to the dummy word line, and then after a second time interval, the supply voltage is applied to the unselected bit line.

16. The method of claim 13, wherein, in a program mode, a first voltage having a voltage greater than or equal to the supply voltage added to a threshold voltage of a string select transistor is applied to the selected string select line during a bit line setup period, and then after a first time interval, the supply voltage is applied to the selected string select line.

17. The method of claim 16, wherein, in the program mode, the first voltage is applied to the selected string select line, and then after a second time interval, the dummy pass voltage is applied to the dummy word line.

18. A memory device, comprising:
a memory cell array comprising a dummy word line, a plurality of bit lines, a plurality of word lines, a string select line and a ground select line; and
a row control circuit configured to generate a program voltage, a pass voltage, and a dummy pass voltage having a voltage in a range between 0 V to the pass voltage, and to control electric potentials of the dummy word line, the plurality of word lines, the string select line and the ground select line,
wherein, in a program mode, the row control circuit applies a supply voltage to the string select line, the dummy pass voltage to the dummy word line, the supply voltage to an unselected bit line of the plurality of bit lines, a voltage of 0 V to a selected bit line of the plurality of bit lines, the pass voltage to a selected word line of the plurality of word lines, the pass voltage to an unselected word line of the plurality of word lines, and a program voltage to the selected word line.

19. The memory device of claim 18, further comprising:
a page buffer circuit comprising a plurality of page buffers corresponding to the plurality of bit lines, respectively;
a common source line control circuit configured to control electric potential of a common source line to be 0 V and then a voltage approximately the supply voltage in the program mode; and
a column gate circuit configured to electrically connect or disconnect the page buffer circuit with an input/output circuit in response to column select signals.

20. The memory device of claim 18, wherein the memory device is a NAND-type flash memory device.
